(19) United States
(12) Patent Application Publication
(10) Pub. No.: US 2024/0385518 A1
(43) Pub. Date: Nov. 21, 2024

(54) RADIATION-SENSITIVE RESIN COMPOSITION, RESIN, COMPOUND, AND PATTERN FORMATION METHOD

(71) Applicant: JSR CORPORATION, Tokyo (JP)

(72) Inventors: Katsuaki NISHIKORI, Tokyo (JP); Kazuya KIRIYAMA, Tokyo (JP); Natsuko KINOSHITA, Tokyo (JP); Takuhiro TANIGUCHI, Tokyo (JP); Takuya OMIYA, Tokyo (JP)

(73) Assignee: JSR CORPORATION, Tokyo (JP)

(21) Appl. No.: 18/691,090

(22) PCT Filed: Sep. 1, 2022
(86) PCT No.: PCT/JP2022/032972

§ 371 Date: Mar. 12, 2024

(30) Foreign Application Priority Data
Oct. 6, 2021 (JP) 2021-164551

(51) Int. Cl. G03F 7/004; G03F 7/039

(52) U.S. Cl. CPC G03F 7/0045; G03F 7/0048; G03F 7/0397

(57) ABSTRACT

A radiation-sensitive resin composition includes a resin including a structural unit (I) represented by formula (1). R^{a} is a hydrogen atom or a substituted or unsubstituted monovalent hydrocarbon group having 1 to 10 carbon atoms; Ar¹ is a substituted or unsubstituted divalent aromatic hydrocarbon group having 6 to 20 carbon atoms; m is 0 or 1; L¹ is a single bond, or —O—, *—COO—, a divalent hydrocarbon group having 1 to 20 carbon atoms, or a combination thereof, and * is a bond on an Ar¹ side; Ar² is a monovalent aromatic hydrocarbon group having 6 to 20 carbon atoms and substituted with X; X is an iodine atom or a bromine atom; and n₁ is an integer of 1 to nₘₐₓ, wherein nₘₐₓ is the number of Xs when all hydrogen atoms in the monovalent aromatic hydrocarbon group represented by the Ar² are substituted with X.

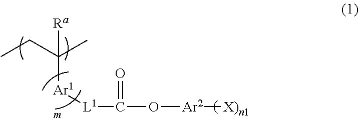

### TECHNICAL FIELD

The present invention relates to a radiation-sensitive resin composition, a resin, a compound, and a pattern formation method.

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a resin into an alkaline or organic developer between an exposed part and a non-exposed part.

In the photolithography technology, pattern miniaturization is promoted by using short-wavelength radiation, such as ArF excimer laser or by combining such radiation with an immersion exposure method (liquid immersion lithography). As a next-generation technology, further short-wavelength radiation, such as an electron beam, an X-ray, and EUV (extreme ultraviolet) is being utilized, and a resist material containing a styrene-based resin having enhanced radiation absorption efficiency is also being studied (Patent Document 1).

### PRIOR ART DOCUMENT

### Patent Document

Patent Document 1: JP-B-4958584

### SUMMARY OF THE INVENTION

### Problems to be Solved by the Invention

Even in the above-described next generation technology, various resist performances equivalent to or higher than conventional performances are required in sensitivity and critical dimension uniformity (CDU) performance, which is an index of uniformity of a line width and a hole diameter, resolution, and the like.

An object of the present invention is to provide a radiation-sensitive resin composition, a resin, a compound, and a pattern formation method capable of forming a resist film excellent in sensitivity, CDU performance, and resolution when a next-generation technology is applied.

### Means for Solving the Problems

In order to achieve the above object, the present inventors have intensively studied, and as a result have found that the above object can be achieved by using the following. This finding has led to the completion of the present invention.

That is, the present invention relates, in one embodiment, to a radiation-sensitive resin composition including
a resin containing a structural unit (I) represented by the following formula (1),
a radiation-sensitive acid generator containing an organic acid anion moiety and an onium cation moiety, and
a solvent

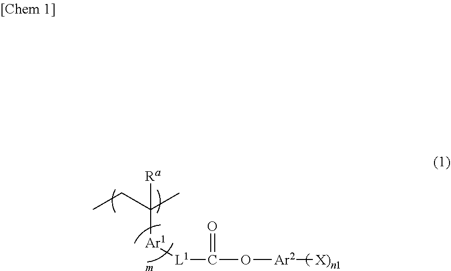

(in the formula (1),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on the Ar¹ side,
Ar² is a substituted or unsubstituted monovalent aromatic hydrocarbon group having 6 to 20 carbon atoms,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 to (the number of hydrogen atoms in the monovalent aromatic hydrocarbon group represented by the Ar²).)

Since the radiation-sensitive resin composition includes the resin containing the structural unit (I), the radiation-sensitive resin composition can exhibit sensitivity, CDU performance, and resolution at a sufficient level. The reason for this is not clear, but can be expected as follows. In the structural unit (I), the aromatic hydrocarbon group substituted with an iodine atom or a bromine atom (hereinafter, also referred to as a “specific aromatic hydrocarbon group”) is introduced. As a result, the energy absorption efficiency during exposure is improved, and the acid generation efficiency is enhanced, so that the sensitivity can be improved. However, only when the specific aromatic hydrocarbon group is introduced, the solubility of the resin in an alkaline developer is deteriorated, so that the CDU performance and resolution are deteriorated. On the other hand, by introducing the ester structure of the specific aromatic hydrocarbon group as an alkali-dissociable group, a carboxy group is generated during development, which enhances the solubility of the resin in an alkaline developer. As a result, CDU performance and resolution can be improved.

The present invention relates, in one embodiment, to
a resin including a structural unit (I) represented by the following formula (1),

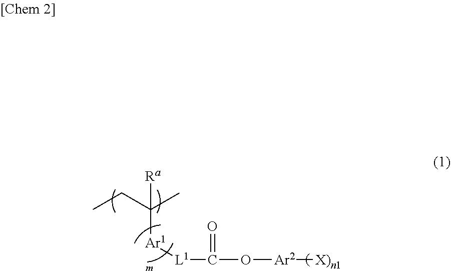

(in the formula (1),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on the Ar¹ side,
Ar² is a substituted or unsubstituted monovalent aromatic hydrocarbon group having 6 to 20 carbon atoms,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 to (the number of hydrogen atoms in the monovalent aromatic hydrocarbon group represented by the Ar²).)

According to the resin, due to the coexistence of the specific aromatic hydrocarbon group and the alkali-dissociable group, excellent sensitivity, CDU performance, and resolution can be imparted to the radiation-sensitive resin composition containing the same.

The present invention relates, in one embodiment, to
a compound represented by the following formula (i),

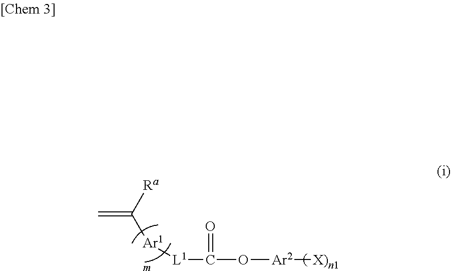

(in the formula (i),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on the Ar¹ side,
Ar² is a substituted or unsubstituted monovalent aromatic hydrocarbon group having 6 to 20 carbon atoms,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 to (the number of hydrogen atoms in the monovalent aromatic hydrocarbon group represented by the Ar²).)

According to the compound, since the specific aromatic hydrocarbon group and the alkali-dissociable group coexist, the compound is suitable as a monomer compound necessary for preparation of the resin of the radiation-sensitive resin composition.

The present invention relates to, in another embodiment, a method for forming a pattern, the method including:
directly or indirectly applying the radiation-sensitive resin composition to a substrate to form a resist film,
exposing the resist film, and
developing the exposed resist film with a developer.

In the pattern formation method, the radiation-sensitive resin composition excellent in sensitivity, CDU performance, and resolution is used, and therefore a high-quality resist pattern can be efficiently formed by lithography to which a next-generation exposure technique is applied.

### DETAILED DESCRIPTION OF THE PREFERRED EMBODIMENTS

Hereinbelow, embodiments of the present invention will be described in detail, but the present invention is not limited to these embodiments.

### <<Radiation-Sensitive Resin Composition>>

The radiation-sensitive resin composition (hereinafter, also simply referred to as “composition”) according to the present embodiment contains a resin, a radiation-sensitive acid generator, and a solvent. The composition may contain any other components as long as the desired effect is not impaired.

### <Resin>

The resin is a set of a polymer containing a structural unit (I). The resin may be a base resin that is a main component of the radiation-sensitive resin composition, a high fluorine-content resin that can function as a modifier or the like for the surface of the resist film, or a mixture thereof.

### (Base Resin)

In addition to the structural unit (I), the base resin may contain a structural unit (II) having a phenolic hydroxyl group, a structural unit (III) having an acid-dissociable group, a structural unit (IV) having a polar group, a structural unit (V) containing a lactone structure or the like, and the like. Each of the structural units will be described below.

### (Structural Unit (I))

The structural unit (I) is represented by the following formula (1).

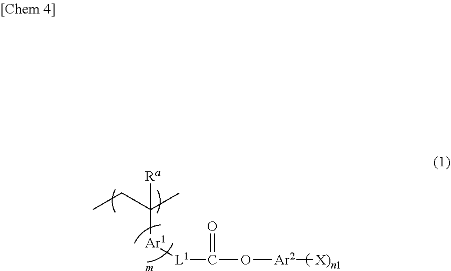

In the formula (1),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on the Ar¹ side,
Ar² is a substituted or unsubstituted monovalent aromatic hydrocarbon group having 6 to 20 carbon atoms,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 to (the number of hydrogen atoms in the monovalent aromatic hydrocarbon group represented by the Ar²).

Examples of the monovalent hydrocarbon group having 1 to 10 carbon atoms represented by the R^{a} include a monovalent chain hydrocarbon group having 1 to 10 carbon atoms, a monovalent alicyclic hydrocarbon group having 3 to 10 carbon atoms, and a monovalent aromatic hydrocarbon group having 6 to 10 carbon atoms.

Examples of the chain hydrocarbon group having 1 to 10 carbon atoms include a linear chain or branched chain saturated hydrocarbon group having 1 to 10 carbon atoms and a linear chain or branched chain unsaturated hydrocarbon group having 1 to 10 carbon atoms. Examples of the linear chain or branched chain saturated hydrocarbon group having 1 to 10 carbon atoms include alkyl groups such as a methyl group, an ethyl group, a n-propyl group, an i-propyl group, a n-butyl group, a 2-methylpropyl group, a 1-methylpropyl group, and a t-butyl group. Examples of the linear chain or branched chain unsaturated hydrocarbon group having 1 to 10 carbon atoms include alkenyl groups such as an ethenyl group, a propenyl group, and a butenyl group; and alkynyl groups such as an ethynyl group, a propynyl group, and a butynyl group.

Examples of the alicyclic hydrocarbon group having 3 to 10 carbon atoms include a monocyclic or polycyclic saturated hydrocarbon group and a monocyclic or polycyclic unsaturated hydrocarbon group. Preferred examples of the monocyclic saturated hydrocarbon groups include a cyclopentyl group, a cyclohexyl group, a cycloheptyl group, and a cyclooctyl group. Preferred examples of the polycyclic cycloalkyl group include bridged alicyclic hydrocarbon groups such as a norbornyl group, an adamantyl group, and a tricyclodecyl group. It is to be noted that the bridged alicyclic hydrocarbon group refers to a polycyclic alicyclic hydrocarbon group in which two carbon atoms that are not adjacent to each other among carbon atoms composing an alicyclic ring are bonded by a chemical bond containing one or more carbon atoms.

Examples of the monovalent aromatic hydrocarbon group having 6 to 10 carbon atoms include aryl groups such as a phenyl group, a tolyl group, a xylyl group, and a naphthyl group; and aralkyl groups such as a benzyl group and a phenethyl group.

As the R^{a}, a hydrogen atom or a monovalent chain hydrocarbon group having 1 to 10 carbon atoms is preferable, and a hydrogen atom or a linear chain saturated hydrocarbon group having 1 to 5 carbon atoms is more preferable.

A part or all of the hydrogen atoms of the hydrocarbon group of the R^{a} may be substituted with a substituent. Examples of the substituent include halogen atoms such as a fluorine atom, a chlorine atom, a bromine atom, and an iodine atom, a hydroxy group, a carboxy group, a cyano group, a nitro group, an alkoxy group, an alkoxycarbonyl group, an alkoxycarbonyloxy group, an acyl group, and an acyloxy group.

Examples of the divalent aromatic hydrocarbon group having 6 to 20 carbon atoms represented by the Ar¹ include groups obtained by removing two hydrogen atoms from an aromatic hydrocarbon ring having 6 to 20 carbon atoms such as a benzene ring, a naphthalene ring, an anthracene ring, a phenalene ring, a phenanthrene ring, a pyrene ring, a fluorene ring, and a perylene ring. The Ar¹ is preferably a divalent aromatic hydrocarbon group having 6 to 10 carbon atoms, more preferably a benzene ring.

A part or all of the hydrogen atoms of the aromatic hydrocarbon group of the Ar¹ may be substituted with a substituent. As the substituent, the substituent in the R^{a} can be suitably employed.

As the divalent hydrocarbon group having 1 to 20 carbon atoms in the L¹, groups obtained by further removing one hydrogen atom from a group (for example, a tetracyclodecyl group, an anthryl group, or an anthracenyl group) obtained by extending the carbon number of the monovalent hydrocarbon group having 1 to 10 carbon atoms represented by the R^{a} to 20 can be suitably employed.

The L¹ is preferably —R^{La}—, —(R^{Lb})_{β}—R^{Lc}—, or *—COOR^{Ld}—. β is 0 or 1. * is a bond on the Ar¹ side. Here, R^{La}, R^{Lb}, R^{Lc}, and R^{Ld} are each independently a divalent hydrocarbon group having 1 to 20 carbon atoms. As the divalent hydrocarbon group having 1 to 20 carbon atoms represented by R^{La}, R^{Lb}, R^{Lc}, and R^{Ld}, the divalent hydrocarbon group having 1 to 20 carbon atoms in the L¹ can be suitably employed. Among them, a divalent chain hydrocarbon group having 1 to 10 carbon atoms or a divalent aromatic hydrocarbon group having 6 to 12 carbon atoms is preferable, a divalent linear chain hydrocarbon group having 1 to 5 carbon atoms or a divalent aromatic hydrocarbon group having 6 to 10 carbon atoms is more preferable, and a methanediyl group, an ethanediyl group, or a benzenediyl group is still more preferable.

Examples of the monovalent aromatic hydrocarbon group having 6 to 20 carbon atoms represented by the Ar² include groups obtained by removing one hydrogen atom from the aromatic hydrocarbon ring having 6 to 20 carbon atoms in the Ar¹. Among them, a phenyl group, a naphthyl group, and a benzyl group are preferable.

A part or all of the hydrogen atoms of the monovalent aromatic hydrocarbon group of the Ar² are substituted with an iodine atom or a bromine atom represented by X, but a part or all of the remaining hydrogen atoms may be substituted with a substituent other than X. As the substituent, the substituent in the R^{a} (with the exception of an iodine atom and a bromine atom) can be suitably employed.

X is preferably an iodine atom from the viewpoint of sensitivity.

The lower limit of n₁ is 1. The upper limit of n₁ is the number of hydrogen atoms of the monovalent aromatic hydrocarbon group of the Ar². For example, when Ar² is a phenyl group, n₁ is an integer of 1 to 5. When Ar² is a naphthyl group, n₁ is an integer of 1 to 7.

The structural unit (I) is preferably at least one of a structural unit represented by the following formula (1-1) (hereinafter, also referred to as a “structural unit (I-1)”) and a structural unit represented by the following formula (1-2) (hereinafter, also referred to as a “structural unit (I-2)”).

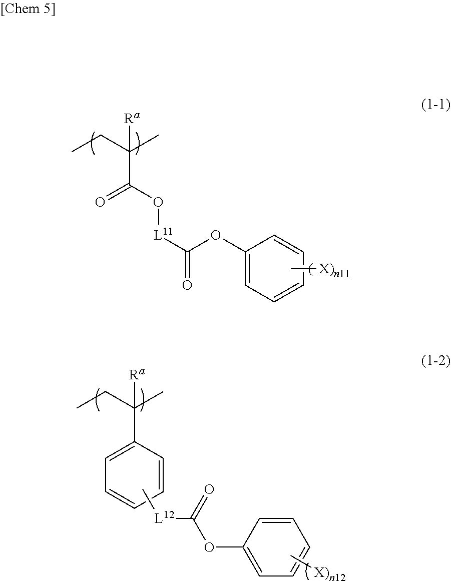

(in the formula (1-1),
R^{a} and X have the same meaning as in the formula (1),
L¹¹ is a divalent chain hydrocarbon group having 1 to 10 carbon atoms or a divalent alicyclic hydrocarbon group having 3 to 12 carbon atoms, and
n₁₁ is an integer of 1 to 5.

In the formula (1-2),
R^{a} and X have the same meaning as in the formula (1),
L¹² is **—(R^{12a})_{γ}—O—R^{12b}— or **—COOR^{12c}—, R^{12a}, R^{12b}, and R^{12c} are each independently a divalent chain hydrocarbon group having 1 to 10 carbon atoms or a divalent alicyclic hydrocarbon group having 3 to 12 carbon atoms, ** is a bond directly linked to a benzene ring, and γ is 0 or 1, and
n₁₂ is an integer of 1 to 5.)

Examples of the divalent chain hydrocarbon group having 1 to 10 carbon atoms represented by the L¹¹ include groups obtained by further removing one hydrogen atom from the monovalent chain hydrocarbon group having 1 to 10 carbon atoms in the R^{a}. Examples of the divalent alicyclic hydrocarbon group having 3 to 12 carbon atoms represented by the L¹¹ include groups obtained by further removing one hydrogen atom from a group (for example, a tetracyclodecyl group) obtained by extending the carbon number of the monovalent alicyclic hydrocarbon group having 3 to 10 carbon atoms in the R^{a} to 12. As the L¹¹, a divalent chain hydrocarbon group having 1 to 10 carbon atoms is preferable, a divalent linear chain hydrocarbon group having 1 to 5 carbon atoms is more preferable, and a methanediyl group or an ethanediyl group is still more preferable.

The n₁₁ is preferably an integer of 1 to 4, and more preferably an integer of 1 to 3.

In the L¹², as the divalent chain hydrocarbon group having 1 to 10 carbon atoms and the divalent alicyclic hydrocarbon group having 3 to 12 carbon atoms represented by R^{12a}, R^{12b}, and R^{12c}, the divalent chain hydrocarbon group having 1 to 10 carbon atoms and the divalent alicyclic hydrocarbon group having 3 to 12 carbon atoms each represented by the L¹¹ can be suitably employed.

The n₁₂ is preferably an integer of 1 to 4, and more preferably an integer of 1 to 3.

The structural unit (I) is preferably represented by the following formulae (I-1) to (I-27).

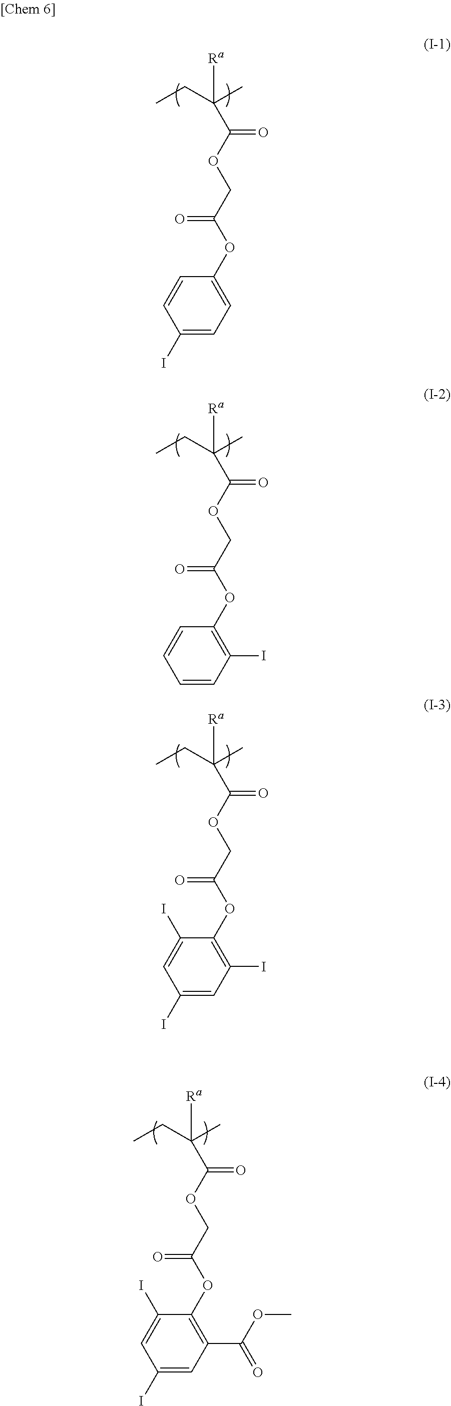

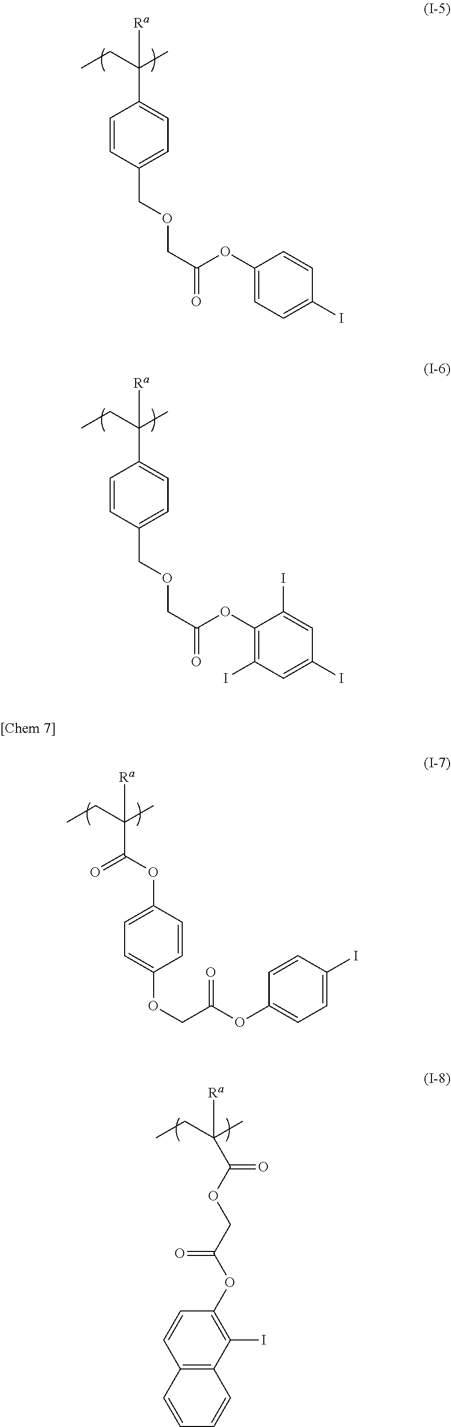

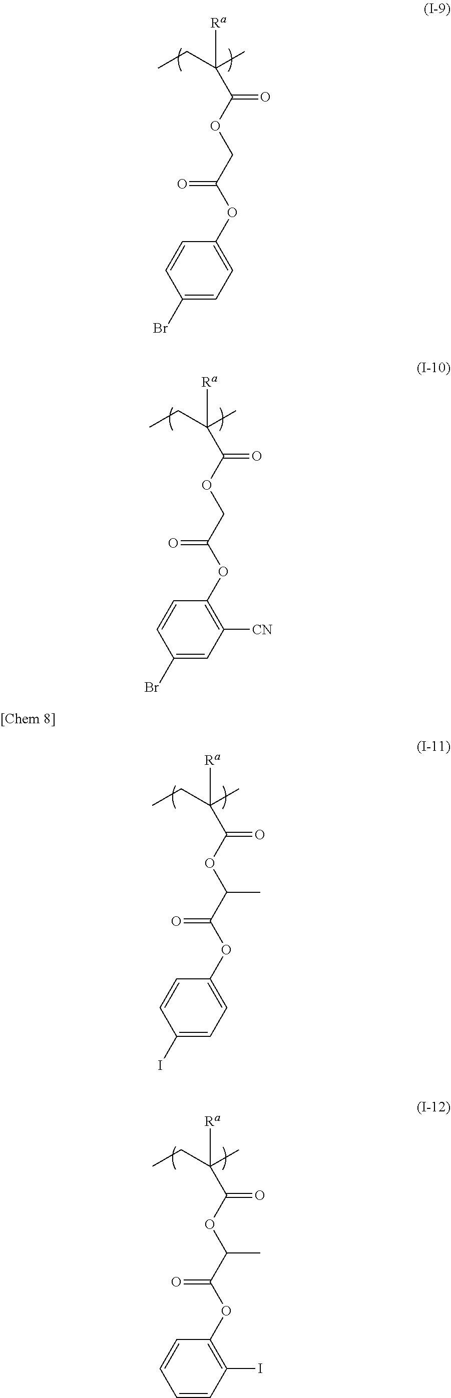

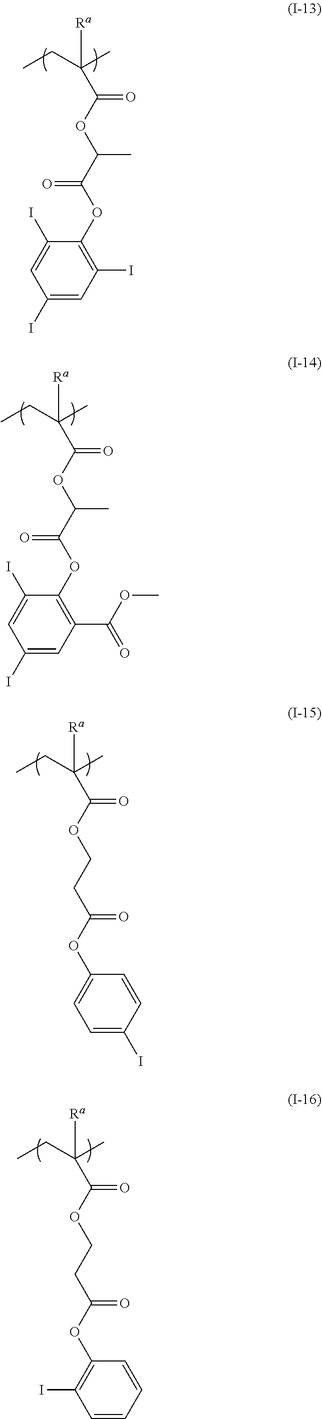

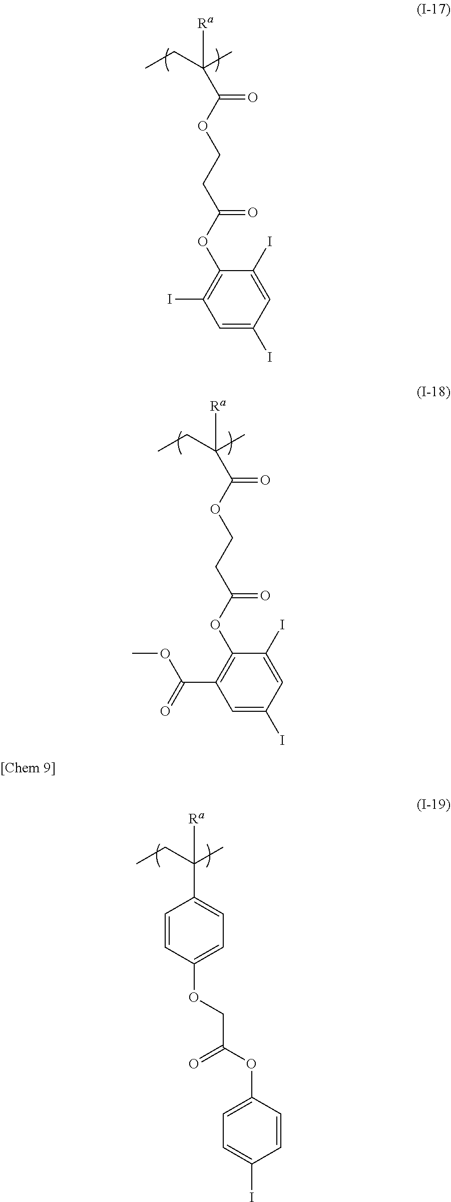

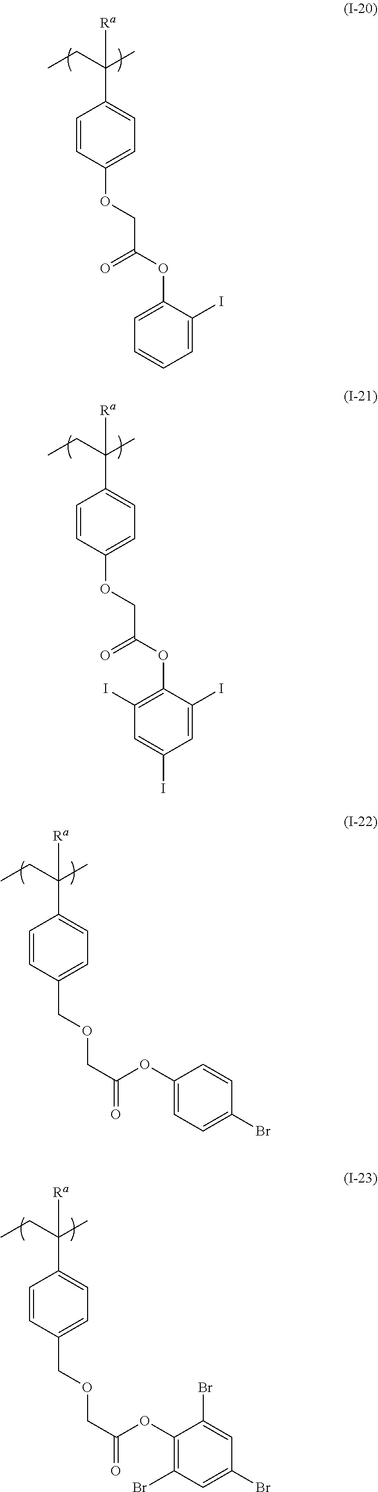

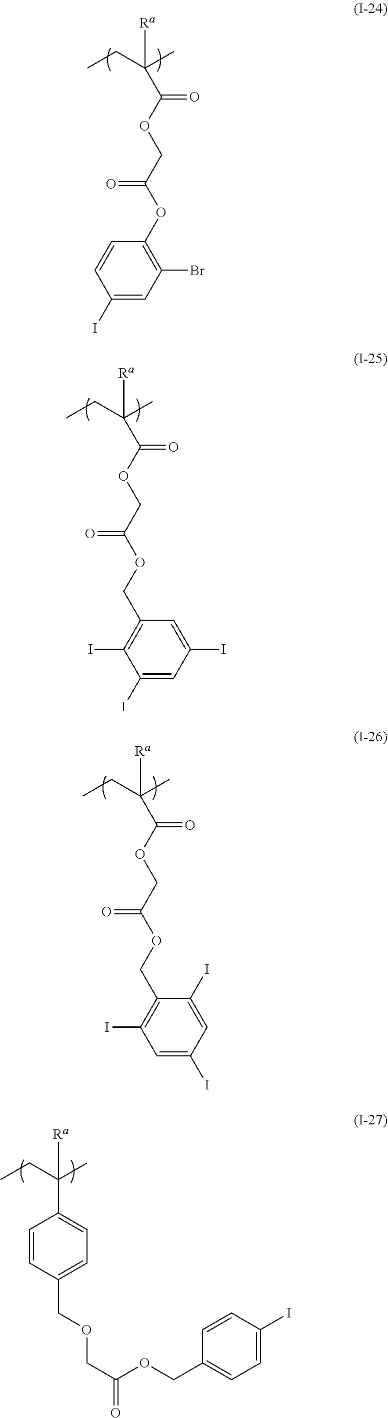

In the formulae (I-1) to (I-27), R^{a} has the same meaning as in the formula (1).

The lower limit of the content of the structural unit (I) to all structural units composing the base resin (the total content when a plurality of structural units (I) are present) is preferably 1 mol %, more preferably 5 mol %, still more preferably 10 mol %, and particularly preferably 15 mol %. The upper limit of the content is preferably 50 mol %, more preferably 40 mol %, and still more preferably 25 mol %. When the content of the structural unit (I) is adjusted to within the above range, the radiation-sensitive resin composition can further improve the sensitivity, CDU performance, and resolution of the resist film.

(Method for Synthesizing Monomer Compound that Gives Structural Unit (I))

The monomer compound that gives the structural unit (I) can be synthesized by subjecting a hydroxyaryl halide and a halide of an acyl halide (for example, chloroacetyl chloride) to a nucleophilic substitution reaction to form an ester, and further subjecting the ester to a nucleophilic substitution reaction with a polymerizable group-containing carboxylic acid or a polymerizable group-containing alcohol, as representatively shown in the following scheme.

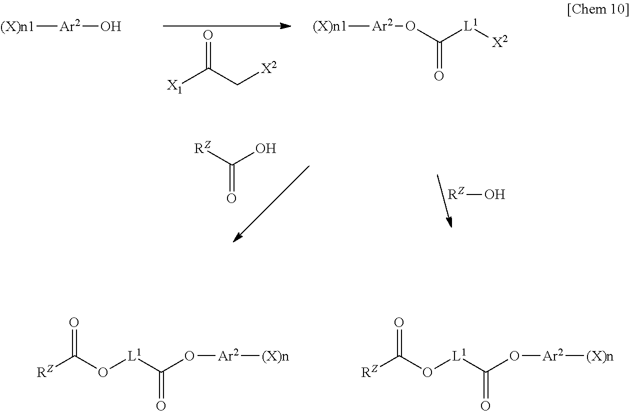

(In the scheme, Ar², X, n₁, and L¹ have the same meaning as in the formula (1). X¹ and X² are halogen atoms. R^{Z} is a polymerizable group-containing group.)

Other structures can also be appropriately synthesized by changing the structures of starting materials, halides of acyl halides, and polymerizable group-containing carboxylic acids.

### [Structural Unit (II)]

The base resin preferably contains a structural unit (II) having a phenolic hydroxyl group. When the resin has the structural unit (II) and another structural unit as necessary, the solubility in a developer can be more appropriately adjusted, and as a result, the sensitivity and the like of the radiation-sensitive resin composition can be further improved. When KrF excimer laser light, EUV, electron beam or the like is used as radiation to be applied in an exposure step in a pattern formation method, the structural unit (II) contributes to improvement in etching resistance and improvement in the difference in solubility in a developer between an exposed area and an unexposed area (namely, dissolution contrast). In particular, the structural unit (IV) can be suitably applied to pattern formation using exposure with a radioactive ray having a wavelength of 50 nm or less, such as an electron beam or EUV.

The structural unit (II) is preferably represented by the following formula (2),

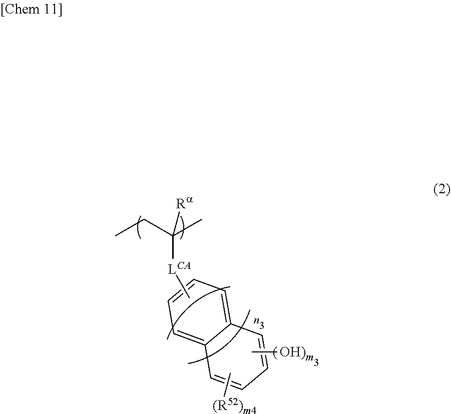

(in the formula (2),
R^{a} is a hydrogen atom, a fluorine atom, a methyl group, or a trifluoromethyl group,
L^{CA} is a single bond, —COO—*, or —O—*, and * is a bond on the aromatic ring side,
R⁵² is a cyano group, a nitro group, an alkyl group, a fluorinated alkyl group, an alkoxycarbonyloxy group, an acyl group, or an acyloxy group, and when two or more R⁵²s are present, the R⁵²s are the same as or different from each other, and
n₃ is an integer of 0 to 2, m₃ is an integer of 1 to 8, and m₄ is an integer of 0 to 8, provided that 1≤m₃+m₄≤2n₃+5 is satisfied.)

The R^{α} is preferably a hydrogen atom or a methyl group from the viewpoint of the copolymerizability of a monomer that affords the structural unit (II).

The L^{CA} is preferably a single bond or —COO—*.

R⁵² is a cyano group, a nitro group, an alkyl group, a fluorinated alkyl group, an alkoxycarbonyloxy group, an acyl group, or an acyloxy group. Examples of the alkyl group include linear chain or branched alkyl groups having 1 to 8 carbon atoms such as a methyl group, an ethyl group, and a propyl group. Examples of the fluorinated alkyl group include linear chain or branched fluorinated alkyl groups having 1 to 8 carbon atoms such as a trifluoromethyl group and a pentafluoroethyl group. Examples of the alkoxycarbonyloxy group include chain or alicyclic alkoxycarbonyloxy groups having 2 to 16 carbon atoms such as a methoxycarbonyloxy group, a butoxycarbonyloxy group, and an adamantylmethyloxycarbonyloxy group. Examples of the acyl group include aliphatic or aromatic acyl groups having 2 to 12 carbon atoms such as an acetyl group, a propionyl group, a benzoyl group, and an acryloyl group. Examples of the acyloxy group include aliphatic or aromatic acyloxy groups having 2 to 12 carbon atoms such as an acetyloxy group, a propionyloxy group, a benzoyloxy group, and an acryloyloxy group.

The n₃ is preferably 0 or 1, and more preferably 0.

The m₃ is preferably an integer of 1 to 3, and more preferably 1 or 2.

The m₄ is preferably an integer of 0 to 3, and more preferably an integer of 0 to 2.

As the structural unit (II), structural units represented by the following formulae (2-1) to (2-10) (hereinafter, also referred to as “structural units (2-1) to (2-10)”) and the like are preferable.

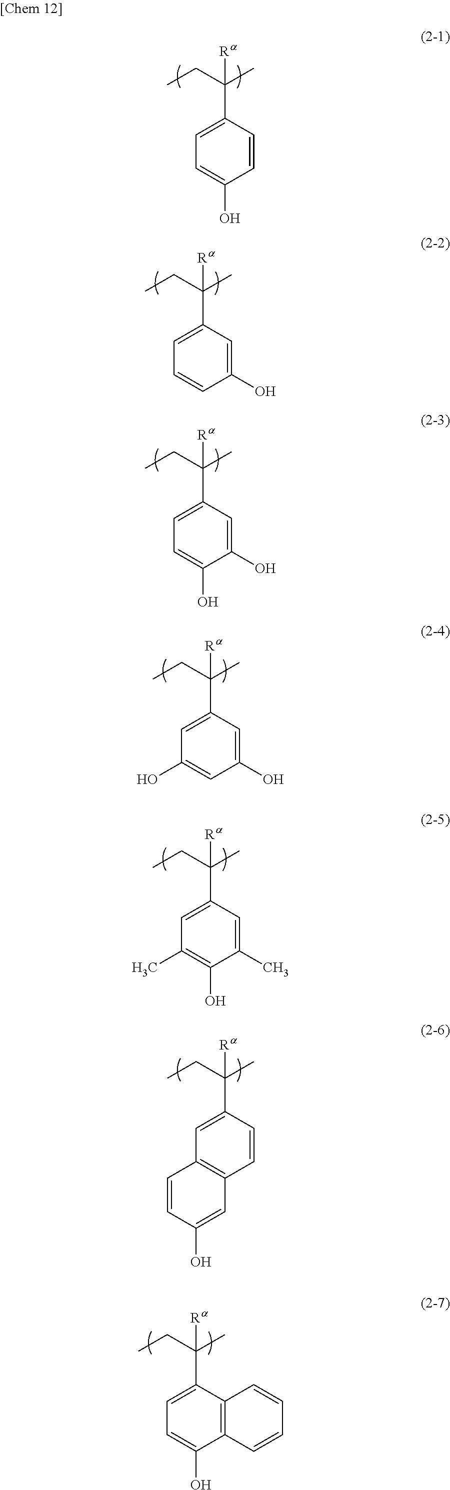

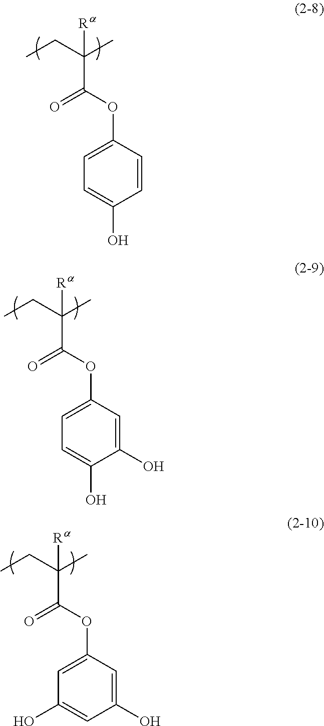

In the formulae (2-1) to (2-10), R^{α} is the same as in the formula (2).

Among them, the structural units (2-1) to (2-4), (2-6), and (2-8) are preferable.

When the base resin contains the structural unit (II), the lower limit of the content of the structural unit (II) to all structural units composing the base resin (the total content when a plurality of structural units (II) are present) is preferably 15 mol %, more preferably 20 mol %, and still more preferably 25 mol %. The upper limit of the content is preferably 70 mol %, more preferably 65 mol %, and still more preferably 60 mol %. When the content of the structural unit (II) is adjusted to within the above range, the sensitivity, CDU performance, and resolution of the radiation-sensitive resin composition can be further improved.

In the case of polymerizing a monomer having a phenolic hydroxy group such as hydroxystyrene, the structural unit (II) can be obtained by performing polymerization in a state where the phenolic hydroxyl group is protected by a protecting group, and then performing deprotection. Examples of the protecting group may include acid-dissociable groups such as an ethoxyethyl group and an alkali-dissociable group, and among them, an acid-dissociable group is preferable, and an acetal protecting group is more preferable.

### (Structural Unit (III))

The base resin preferably contains a structural unit (III) having an acid-dissociable group. The “acid-dissociable group” refers to a group that substitutes for a hydrogen atom of alkali-soluble groups such as a carboxy group, a phenolic hydroxyl group, a sulfo group, and a sulfonamide group, and is dissociated by the action of an acid. Therefore, the acid-dissociable group is bonded to an oxygen atom that would otherwise be bonded to the hydrogen atom in these functional groups. The structural unit (III) is preferably represented by the following formula (3) from the viewpoint of improving the pattern-forming performance of the radiation-sensitive resin composition.

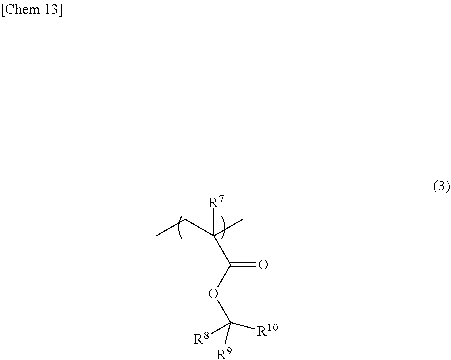

In the formula (3), R⁷ is a hydrogen atom, a fluorine atom, a methyl group, or a trifluoromethyl group, R⁸ is a a monovalent hydrocarbon group having 1 to 20 carbon atoms, R⁹ and R¹⁰ are each independently a monovalent chain hydrocarbon group having 1 to 10 carbon atoms or a monovalent alicyclic hydrocarbon group having 3 to 20 carbon atoms, or R⁹ and R¹⁰ represent a divalent alicyclic group having 3 to 20 carbon atoms which R⁹ and R¹⁰ are combined to form together with a carbon atom to which R⁹ and R¹⁰ are bonded.

From the viewpoint of copolymerizability of a monomer that will give the structural unit (III), R⁷ is preferably a hydrogen atom or a methyl group, more preferably a methyl group.

Examples of the monovalent hydrocarbon group having 1 to 20 carbon atoms represented by R⁸ include a chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the chain hydrocarbon groups having 1 to 10 carbon atoms represented by R⁸ to R¹⁰ include linear or branched saturated hydrocarbon groups having 1 to 10 carbon atoms and linear or branched unsaturated hydrocarbon groups having 1 to 10 carbon atoms.

Examples of the alicyclic hydrocarbon groups having 3 to 20 carbon atoms represented by R⁸ to R¹⁰ include monocyclic or polycyclic saturated hydrocarbon groups and monocyclic or polycyclic unsaturated hydrocarbon groups. Preferred examples of the monocyclic saturated hydrocarbon groups include a cyclopentyl group, a cyclohexyl group, a cycloheptyl group, and a cyclooctyl group. Preferred examples of the polycyclic saturated hydrocarbon groups include bridged alicyclic hydrocarbon groups such as a norbornyl group, an adamantyl group, a tricyclodecyl group, and a tetracyclododecyl group. It is to be noted that the bridged alicyclic hydrocarbon group refers to a polycyclic alicyclic hydrocarbon group in which two carbon atoms that constitute an alicyclic ring and not adjacent to each other are bonded by a bonding chain containing at least one carbon atom.

Examples of the monovalent aromatic hydrocarbon group having 6 to 20 carbon atoms represented by R⁸ include: aryl groups such as a phenyl group, a tolyl group, a xylyl group, a naphthyl group, and an anthryl group; and aralkyl groups such as a benzyl group, a phenethyl group, and a naphthylmethyl group.

R⁸ is preferably a linear or branched saturated hydrocarbon group having 1 to 10 carbon atoms or an aromatic hydrocarbon group having 6 to 20 carbon atoms.

The divalent alicyclic group having 3 to 20 carbon atoms which R⁹ and R¹⁰ are combined to form together with a carbon atom to which R⁹ and R¹⁰ are bonded is not particularly limited as long as it is a group obtained by removing two hydrogen atoms from the same carbon atom constituting a carbon ring of a monocyclic or polycyclic alicyclic hydrocarbon having the above-described carbon number. The divalent alicyclic group having 3 to 20 carbon atoms may either be a monocyclic hydrocarbon group or a polycyclic hydrocarbon group. The polycyclic hydrocarbon group may either be a bridged alicyclic hydrocarbon group or a condensed alicyclic hydrocarbon group and may either be a saturated hydrocarbon group or an unsaturated hydrocarbon group. It is to be noted that the condensed alicyclic hydrocarbon group refers to a polycyclic alicyclic hydrocarbon group in which two or more alicyclic rings share their sides (bond between two adjacent carbon atoms).

When the monocyclic alicyclic hydrocarbon group is a saturated hydrocarbon group, preferred examples thereof include a cyclopentanediyl group, a cyclohexanediyl group, a cycloheptanediyl group, and a cyclooctanediyl group. When the monocyclic alicyclic hydrocarbon group is an unsaturated hydrocarbon group, preferred examples thereof include a cyclopentenediyl group, a cyclohexenediyl group, a cycloheptenediyl group, a cyclooctenediyl group, and a cyclodecenediyl group. The polycyclic alicyclic hydrocarbon group is preferably a bridged alicyclic saturated hydrocarbon group, and preferred examples thereof include a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group).

Among them, R⁸ is preferably an alkyl group having 1 to 4 carbon atoms or a phenyl group, and the alicyclic structure which R⁹ and R¹⁰ are combined to form together with a carbon atom to which R⁹ and R¹⁰ are bonded is preferably a polycyclic or monocyclic cycloalkane structure.

Examples of the structural unit (III-1) include structural units represented by the following formulas (3-1) to (3-7) (hereinafter also referred to as “structural units (III-1-1) to (III-1-7)”).

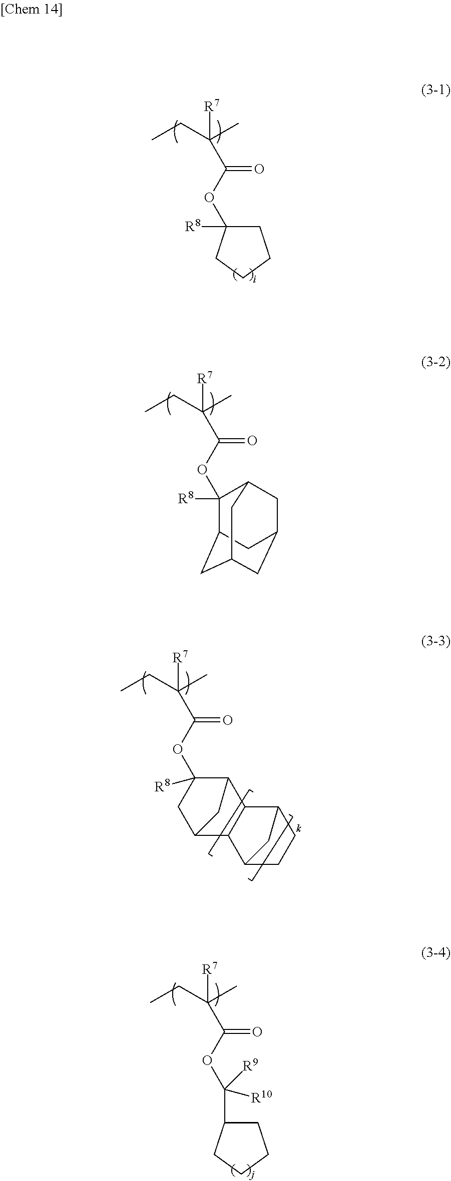

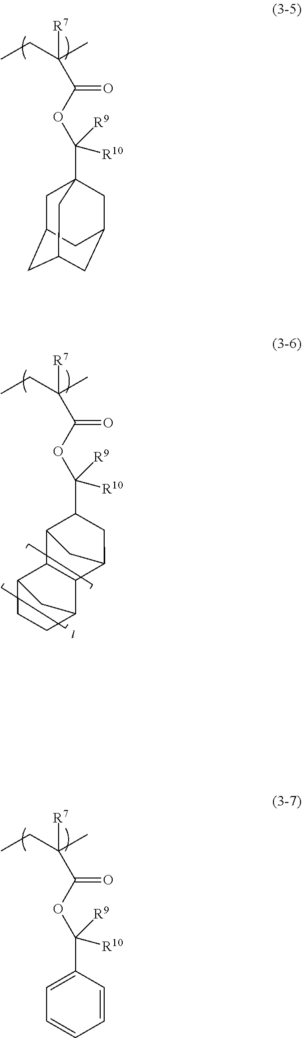

In the formulas (3-1) to (3-7), R⁷ to R¹⁰ have the same meaning as in the formula (3), i and j are each independently an integer of 1 to 4, and k and 1 are each 0 or 1.

In the formulas (3-1) to (3-7), i and j are preferably 1, and R⁸ is preferably a methyl group, an ethyl group, an isopropyl group, or a phenyl group. R⁹ and R¹⁰ are each preferably a methyl group, or an ethyl group

The base resin may contain one type or a combination of two or more types of the structural units (III).

The lower limit of a content of the structural unit (III) (a total content when a plurality of types are contained) is preferably 10 mol %, more preferably 20 mol %, still more preferably 30 mol %, and particularly preferably 35 mol % based on all structural units constituting the base resin. The upper limit of the content is preferably 70 mol %, more preferably 60 mol %, still more preferably 55 mol %, and particularly preferably 55 mol %. When the content of the structural unit (III) is set to fall within the above range, the pattern-forming performance of the radiation-sensitive resin composition can further be improved.

### (Structural Unit (IV))

The base resin may appropriately contain a structural unit (IV) having a polar group in addition to the structural units (I) to (III). The polar group also includes ionic functional groups. Examples of the polar group may include a fluorine atom, an alcoholic hydroxyl group, a carboxy group, a cyano group, a nitro group, and a sulfonamide group. Among the structural units (IV), a structural unit having a fluorine atom, a structural unit having an alcoholic hydroxyl group, and a structural unit having a carboxy group are preferable, and a structural unit having a fluorine atom and a structural unit having an alcoholic hydroxyl group are more preferable. The ionic functional group includes an anionic group and a cationic group. The anionic group is preferably a group having a sulfonate anion, and the cationic group is preferably a group having a sulfonium cation.

Examples of the structural unit (IV) include structural units represented by the following formulas.

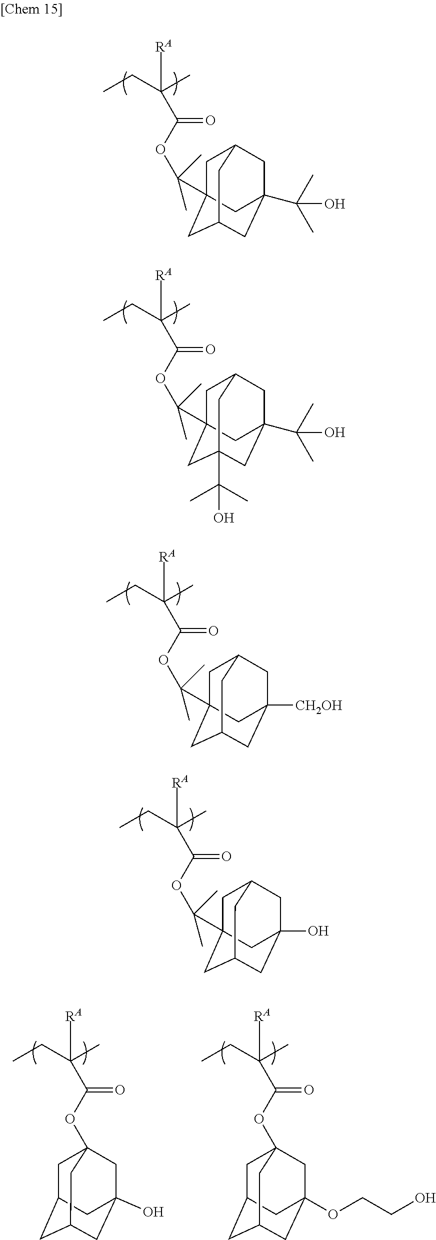

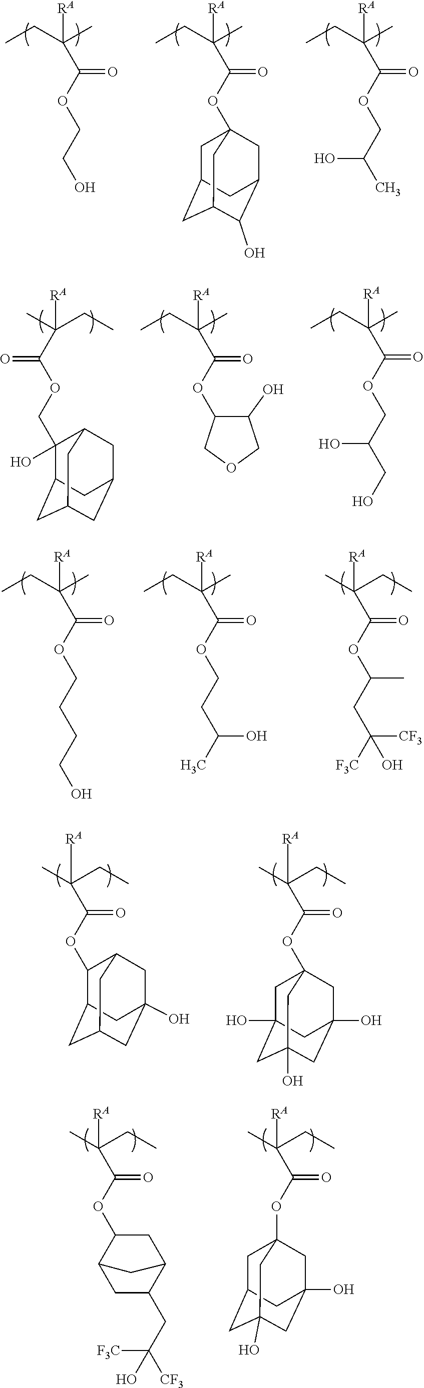

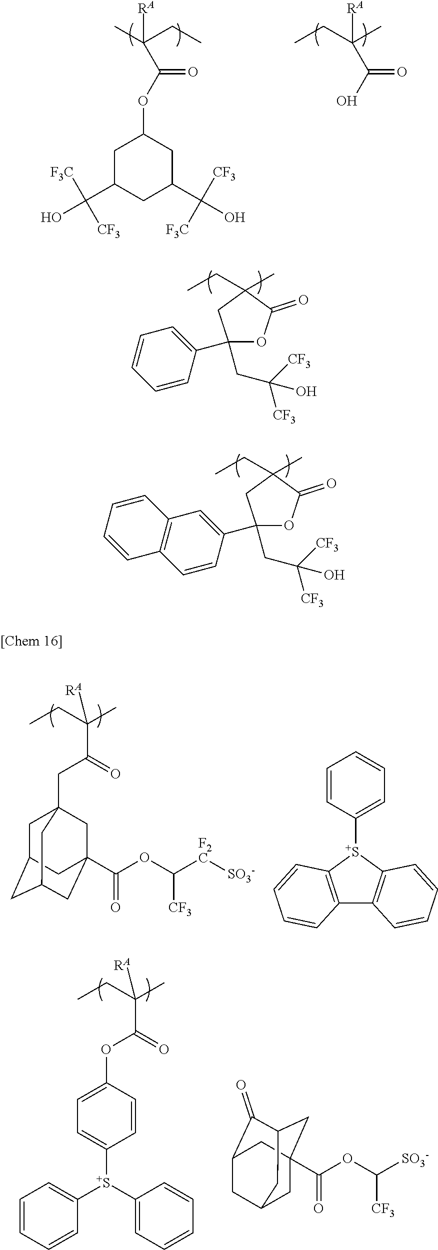

In the formulas, R^{A} is a hydrogen atom, a fluorine atom, a methyl group, or a trifluoromethyl group.

When the base resin contains the structural unit (IV), the lower limit of the content of the structural unit (IV) to all structural units composing the base resin (the total content when a plurality of structural units (IV) are present) is preferably 3 mol %, more preferably 5 mol %, and still more preferably 8 mol %. The upper limit of the content is preferably 30 mol %, more preferably 20 mol %, and even more preferably 15 mol %. When the content of the structural unit (IV) is adjusted to within the above range, the solubility of the resin in a developer can be made more appropriate.

### [Structural Unit (V)]

The structural unit (V) is a structural unit including at least one selected from the group consisting of a lactone structure, a cyclic carbonate structure and a sultone structure. The solubility of the base resin into a developer can be adjusted by further introducing the structural unit (V). As a result, the radiation-sensitive resin composition can provide improved lithography properties such as the resolution. The adhesion between a resist pattern formed from the base resin and a substrate can also be improved.

Among them, the structural unit (V) is preferably a group having a lactone structure, more preferably a group having a norbornane lactone structure, and further preferably a group derived from a norbornane lactone-yl (meth)acrylate.

When the base resin contains the structural unit (V), the lower limit of the content of the structural unit (V) to all structural units composing the base resin (the total content when a plurality of structural units (V) are present) is preferably 5 mol %, more preferably 10 mol %, and still more preferably 15 mol %. The upper limit of the content is preferably 40 mol %, more preferably 30 mol %, and still more preferably 20 mol %. When the content of the structural unit (V) is adjusted to within the range, the lithographic performance, such as resolution, of the radiation-sensitive resin composition and the adhesion between a resist patter to be formed and a substrate can be further improved.

The content of the base resin is preferably 70% by mass or more, more preferably 75% by mass or more, and further preferably 80% by mass or more in the total solid content of the radiation-sensitive resin composition. Here, the “solid” refers to all components except the solvent of the components contained in the radiation-sensitive resin composition.

### (Synthesis Method of Base Resin)

For example, the base resin can be synthesized by performing a polymerization reaction of each monomer for providing each structural unit with a radical polymerization initiator or the like in a suitable solvent.

The molecular weight of the resin as a base resin is not particularly limited, but the weight average molecular weight (Mw) as determined by Gel Permeation Chromatography (GPC) in terms of polystyrene is preferably 1,000 or more and 10,000 or less, more preferably 2,000 or more and 30,000 or less, still more preferably 3,000 or more and 12,000 or less, and particularly preferably 4,000 or more and 8,000 or less. When the Mw of the base resin is less than the lower limit, the heat resistance of the resulting resist film may be deteriorated. When the Mw of the base resin exceeds the above upper limit, the developability of the resist film may be deteriorated.

For the base resin as a base resin, the ratio of Mw to the number average molecular weight (Mn) as determined by GPC relative to standard polystyrene (Mw/Mn) is typically not less than 1 and not more than 5, preferably not less than 1 and not more than 3, and more preferably not less than 1 and not more than 2.

The Mw and Mn of each of the resin and the high fluorine-content resin in the specification are amounts measured by using Gel Permeation Chromatography (GPC) with the condition as described below.
GPC column: two G2000HXL, one G3000HXL, and one G4000HXL (all manufactured from Tosoh Corporation)
Column temperature: 40° C.
Eluting solvent: tetrahydrofuran
Flow rate: 1.0 mL/min
Sample concentration: 1.0% by mass
Sample injection amount: 100 μL
Detector: Differential Refractometer
Reference material: monodisperse polystyrene

### <High Fluorine-Content Resin>

The radiation-sensitive resin composition according to the present embodiment may contain a resin having higher content by mass of fluorine atoms than the above-described base resin (hereinafter, also referred to as a “high fluorine-content resin”) as well as the base resin. When the radiation-sensitive resin composition contains the high fluorine-content resin, the high fluorine-content resin can be localized in the surface layer of a resist film compared to the base resin, which as a result makes it possible to control the state of the resist film surface and the component distribution in the resist film to desired states.

The high fluorine-content resin preferably contains a structural unit having a fluorine atom-containing group (hereinafter, also referred to as a “structural unit (VI)”). The high fluorine-content resin preferably further has any of the structural units (I) and (III) in the base resin, as necessary. As described above, the structural unit (I) represented by the formula (1) may be contained in the base resin or may be contained in the high fluorine-content resin. The aspect in which the high fluorine-content resin has the structural units (I) and (III) is the same as the aspect of the structural units (I) and (III) described for the base resin.

The structural unit (VI) is preferably represented by the following formula (6),

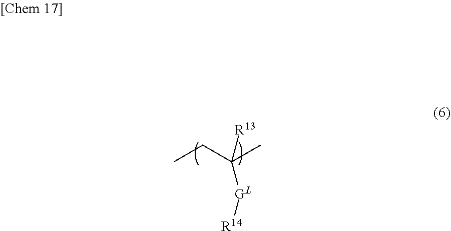

In the formula (6), R¹³ is a hydrogen atom, a methyl group, or a trifluoromethyl group; G^{L} is a single bond, an oxygen atom, a sulfur atom, —COO—, —SO₂ONH—, —CONH—, or —OCONH—; R¹⁴ is a monovalent fluorinated chain hydrocarbon group having a carbon number of 1 to 20, or a monovalent fluorinated alicyclic hydrocarbon group having a carbon number of 3 to 20.

As R¹³ as described above, in terms of the copolymerizability of monomers resulting in the structural unit (VI), a hydrogen atom or a methyl group is preferred, and a methyl group is more preferred.

As G^{L} as described above, in terms of the copolymerizability of monomers resulting in the structural unit, a single bond or —COO— is preferred, and —COO— is more preferred.

Example of the monovalent fluorinated chain hydrocarbon group having a carbon number of 1 to 20 represented by R¹⁴ as described above includes a group in which a part of or all of hydrogen atoms in the straight or branched chain alkyl group having a carbon number of 1 to 20 is/are substituted with a fluorine atom.

Example of the monovalent fluorinated alicyclic hydrocarbon group having a carbon number of 3 to 20 represented by R¹⁴ as described above includes a group in which a part of or all of hydrogen atoms in the monocyclic or polycyclic hydrocarbon group having a carbon number of 3 to 20 is/are substituted with a fluorine atom.

The R¹⁴ as described above is preferably a fluorinated chain hydrocarbon group, more preferably a fluorinated alkyl group, and further preferably 2,2,2-trifluoroethyl group, 1,1,1,3,3,3-hexafluoropropyl group and 5,5,5-trifluoro-1,1-diethylpentyl group.

When the high fluorine-content resin has the structural unit (VI), the lower limit of the content of the structural unit (VI) to all structural units composing the high fluorine-content resin is preferably 40 mol %, more preferably 45 mol %, still more preferably 50 mol %, and particularly preferably 55 mol %. The upper limit of the content is preferably 90 mol %, more preferably 85 mol %, and still more preferably 80 mol %. When the content of the structural unit (VI) is adjusted to within the above range, the mass content of fluorine atoms in the high fluorine-content resin can more appropriately be adjusted and the localization in the surface layer of a resist film can be further promoted.

The lower limit of the Mw of the high fluorine-content resin is preferably 1,000, more preferably 2,000, still more preferably 3,000, and particularly preferably 5,000. The upper limit of the Mw is preferably 50,000, more preferably 30,000, still more preferably 20,000, and particularly preferably 15,000.

The lower limit of the Mw/Mn of the high fluorine-content resin is typically 1, and more preferably 1.1. The upper limit of the Mw/Mn is typically 5, preferably 3, more preferably 2, and further preferably 1.7.

The lower limit of the content of the high fluorine-content resin is preferably 0.1% by mass, more preferably 0.5% by mass, even more preferably 1% by mass, and still even more preferably 1.5% by mass, with respect to the total solid content in the radiation-sensitive resin composition. The upper limit of the content is preferably 20% by mass, more preferably 15% by mass, even more preferably 10% by mass, and particularly preferably 7% by mass.

The lower limit of the content of the high fluorine-content resin is preferably 0.1 parts by mass, more preferably 0.5 parts by mass, still more preferably 1 part by mass, and particularly preferably 1.5 parts by mass, with respect to 100 parts by mass of the base resin. The upper limit of the content is preferably 15 parts by mass, more preferably 10 parts by mass, even more preferably 8 parts by mass, and particularly preferably 5 parts by mass.

When the content of the high fluorine-content resin is adjusted to within the above range, the high fluorine-content resin can be more effectively localized in the surface layer of a resist film, and as a result, the elution of a top portion of a pattern is controlled during development and the rectangularity of a pattern can be enhanced. The radiation-sensitive resin composition may contain one type or two or more types of high fluorine-content resins.

### Method for Synthesizing High Fluorine-Content Resin

The high fluorine-content resin can be synthesized by a method similar to the above-described method for synthesizing a base resin.

### <Radiation-Sensitive Acid Generator>

The radiation-sensitive acid generator is a component that includes an organic acid anion moiety and an onium cation moiety, and generates an acid upon exposure. When the resin contains the structural unit (III) having an acid-dissociable group, the acid generated by exposure can dissociate the acid-dissociable group of the structural unit (III) to generate a carboxy group or the like. This function is different from the function of an acid diffusion controlling agent that suppresses the diffusion of the acid generated from the radiation-sensitive acid generator in the non-exposed part without substantially dissociating the acid-dissociable group or the like of the structural unit (I) or the like of the resin under the pattern formation condition using the radiation-sensitive resin composition. The acid generated from the radiation-sensitive acid generator can be said to be a relatively stronger acid (acid having a smaller pKa) than an acid generated from the acid diffusion controlling agent. Each function of the radiation-sensitive acid generator and the acid diffusion controlling agent depends on energy required for the dissociation of the acid-dissociable group of the structural unit (III) or the like of the resin, and heat energy conditions applied when a pattern is formed using the radiation-sensitive resin composition, and the like. The containing mode of the radiation-sensitive acid generator in the radiation-sensitive resin composition may be a mode in which the radiation-sensitive acid generator is present alone as a compound (released from a polymer), a mode in which the radiation-sensitive acid generator is incorporated as a part of a polymer, or both of these forms, but a mode in which the radiation-sensitive acid generator is present alone as a compound is preferable.

When the radiation-sensitive resin composition contains the radiation-sensitive acid generator, the polarity of the resin in the exposed part increases, whereby the resin in the exposed part is soluble in the developer in the case of alkaline aqueous solution development, and is poorly soluble in the developer in the case of organic solvent development.

Examples of the radiation-sensitive acid generator include an onium salt compound, a sulfonimide compound, a halogen-containing compound, and a diazoketone compound. Examples of the onium salt compound include a sulfonium salt, a tetrahydrothiophenium salt, an iodonium salt, a phosphonium salt, a diazonium salt, and a pyridinium salt. Among them, a sulfonium salt and an iodonium salt are preferable.

Examples of the acid generated during exposure include sulfonic acid. Examples of such an acid include a compound in which the carbon atom adjacent to the sulfo group is substituted with one or more fluorine atoms or fluorinated hydrocarbon groups. Among them, the radiation-sensitive acid generator is preferably a compound composed of an organic acid anion moiety and an onium cation moiety. The organic acid anion moiety preferably has a cyclic structure. The onium cation moiety preferably contains a fluorine-substituted aromatic ring structure (including a structure in which a linking group is interposed between the fluorine atom and the aromatic ring. the same applies hereinafter).

The radiation-sensitive acid generator 1 is preferably represented by the following formula (K-1).

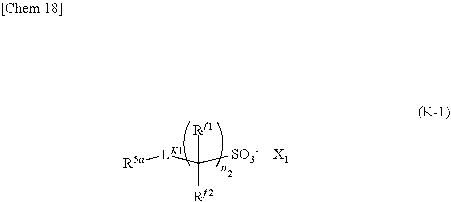

In the formula (K-1), n₂ is an integer of 1 to 5.
R^{f1} and R^{f2} are each independently a hydrogen atom, a fluorine atom, or a fluoroalkyl group. However, when n₂ is 1, at least one of R^{f1} and R^{f2} is a fluorine atom or a fluoroalkyl group. When n₂ is 2 to 5, at least one of two or more R^{f1} and two or more R^{f2} is a fluorine atom or a fluoroalkyl group, the two or more R^{f1} is are the same or different from each other, and the two or more R^{f2}s are the same or different from each other.
L^{K1} is a divalent linking group.
R^{5a} is a monovalent organic group having a cyclic structure.
X₁⁺ is a monovalent onium cation.

In the formula (K-1), n₂ is preferably an integer of 1 to 4, more preferably an integer of 1 to 3, even more preferably 1 or 2.

Examples of the fluoroalkyl group represented by R^{f1} and R^{f2} in the formula (K-1) include fluoroalkyl groups having 1 to 20 carbon atoms. R^{f1} and R^{f2} are each preferably a fluorine atom or a fluoroalkyl group, more preferably a fluorine atom or a perfluoroalkyl group, even more preferably a fluorine atom or a trifluoromethyl group, particularly preferably a fluorine atom.

The divalent linking group represented by L^{K1} in the formula (K-1) is, for example, one kind of group selected from among a divalent linear or branched hydrocarbon group having 1 to 10 carbon atoms, a divalent alicyclic hydrocarbon group having 4 to 12 carbon atoms, —CO—, —O—, —NH—, —S—, and a cyclic acetal structure or a group formed by combining two or more of these groups.

Examples of the divalent linear or branched hydrocarbon group having 1 to 10 carbon atoms include a methanediyl group, an ethanediyl group, a propanediyl group, a butanediyl group, a hexanediyl group, and an octanediyl group. Among them, an alkanediyl group having 1 to 8 carbon atoms is preferred.

Examples of the divalent alicyclic hydrocarbon group having 4 to 12 carbon atoms include: monocyclic cycloalkanediyl groups such as a cyclopentanediyl group and a cyclohexanediyl group; polycyclic cycloalkanediyl groups such as a norbornanediyl group and a adamantanediyl group. Among them, a cycloalkanediyl group having 5 to 12 carbon atoms is preferred.

Examples of the monovalent organic group having a cyclic structure represented by R^{5a} include a monovalent group containing an alicyclic structure having 5 or more ring atoms, a monovalent group containing an aliphatic heterocyclic structure having 5 or more ring atoms, a monovalent group containing an aromatic ring structure having 6 or more ring atoms, and a monovalent group containing an aromatic heterocyclic structure having 5 or more ring atoms. The radiation-sensitive acid generator according to the present embodiment also includes the radiation-sensitive acid generator 1 represented by the formula (K-1) incorporated as part of the polymer by bonding to the polymer at the monovalent organic group represented by R^{5a}.

Examples of the alicyclic structure having 5 or more ring atoms include:
monocyclic cycloalkane structures such as a cyclopentane structure, a cyclohexane structure, a cycloheptane structure, a cyclooctane structure, a cyclononane structure, a cyclodecane structure, and a cyclododecane structure;
monocyclic cycloalkene structures such as a cyclopentene structure, a cyclohexene structure, a cycloheptene structure, a cyclooctene structure, and a cyclodecene structure;
polycyclic cycloalkane structures such as a norbornane structure, an adamantane structure, a tricyclodecane structure, and a tetracyclododecane structure; and
polycyclic cycloalkene structures such as a norbornene structure and a tricyclodecene structure.

Examples of the aliphatic heterocyclic structure having 5 or more ring atoms include:
lactone structures such as a pentanolactone structure, a hexanolactone structure, and a norbornanelactone structure;
sultone structures such as a pentanosultone structure, a hexanosultone structure, and a norbornanesultone structure;
oxygen atom-containing heterocyclic structures such as an oxacyclopentane structure, an oxacycloheptane structure, an oxanorbornane structure, and a cyclic acetal structure;
nitrogen atom-containing heterocyclic structures such as an azacyclopentane structure, an azacyclohexane structure, and diazabicyclooctane structure; and
sulfur atom-containing heterocyclic structures such as a thiacyclopentane structure, a thiacyclohexane structure, and a thianorbornane structure.

Examples of the aromatic ring structure having 6 or more ring atoms include a benzene structure, a naphthalene structure, a phenanthrene structure, and an anthracene structure.

Examples of the aromatic heterocyclic structure having 5 or more ring atoms include: oxygen atom-containing heterocyclic structures such as a furan structure, a pyran structure, and a benzopyran structure; and nitrogen atom-containing heterocyclic structures such as a pyridine structure, a pyrimidine structure, and an indole structure.

The lower limit of the number of ring atoms of the cyclic structure represented by R^{5a} may be 5, but is preferably 6, more preferably 7, even more preferably 8. On the other hand, the upper limit of the number of ring atoms is preferably 15, more preferably 14, even more preferably 13, particularly preferably 12. When the number of ring atoms is set to fall within the above range, the diffusion length of the acid can more appropriately be reduced, which as a result makes it possible to further improve various performances of the radiation-sensitive resin composition.

Part or all of hydrogen atoms of the ring structure in R^{5a} may be substituted by a substituent. Examples of the substituent include halogen atoms such as a fluorine atom, a chlorine atom, a bromine atom, and an iodine atom, a hydroxyl group, a carboxyl group, a cyano group, a nitro group, an alkoxy group, an alkoxycarbonyl group, an alkoxycarbonyloxy group, an acyl group, and an acyloxy group. Among them, a hydroxyl group is preferred.

Among them, R^{5a} is preferably a monovalent group including an alicyclic structure having 5 or more ring atoms or a monovalent group including an aliphatic heterocyclic structure having 5 or more ring atoms, more preferably a monovalent group including an alicyclic structure having 6 or more ring atoms or a monovalent group including an aliphatic heterocyclic structure having 6 or more ring atoms, even more preferably a monovalent group including an alicyclic structure having 9 or more ring atoms or a monovalent group including an aliphatic heterocyclic structure having 9 or more ring atoms, even more preferably an adamantly group, a hydroxyadamantyl group, a norbornanelacton-yl group, a norbornanesulton-yl group, or 5-oxo-4-oxatricyclo[4.3.1.13,8]undecan-yl group, particularly preferably an adamantly group.

An example of the monovalent onium cation represented by X₁⁺ is a radioactive ray-degradable onium cation containing an element such as S, I, O, N, P, Cl, Br, F, As, Se, Sn, Sb, Te, or Bi. Examples of such a radioactive ray-degradable onium cation include a sulfonium cation, a tetrahydrothiophenium cation, a iodonium cation, a phosphonium cation, a diazonium cation, and a pyridinium cation. Among them, a sulfonium cation or a iodonium cation is preferred. The sulfonium cation or the iodonium cation is preferably represented by any of the following formulas (X-1) to (X-5).

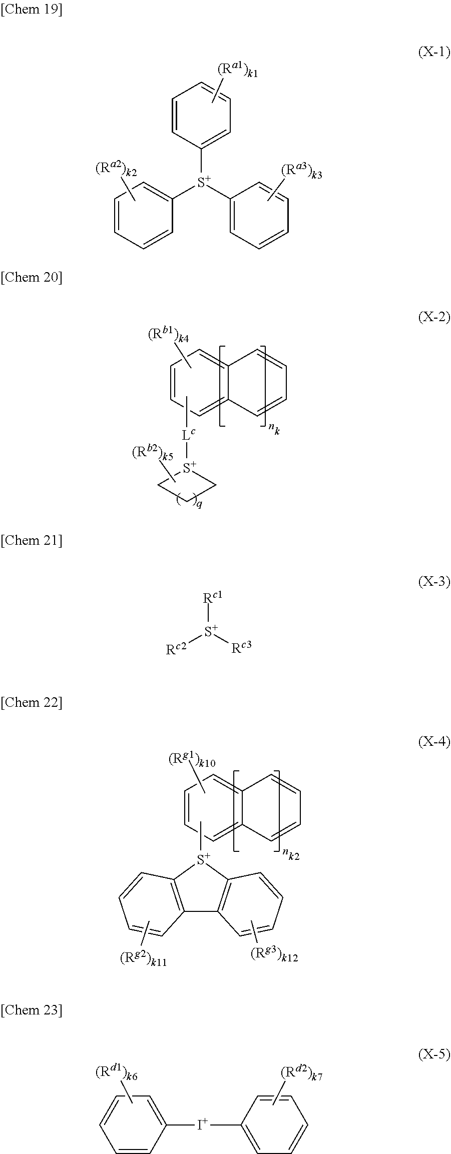

In the formula (X-1), R^{a1}, R^{a2} and R^{a3} are each independently a substituted or unsubstituted, straight or branched chain alkyl group, alkoxy group or alkoxycarbonyloxy group having a carbon number of 1 to 12; a substituted or unsubstituted, monocyclic or polycyclic cycloalkyl group having a carbon number of 3 to 12; a substituted or unsubstituted aromatic hydrocarbon group having a carbon number of 6 to 12; a hydroxy group, a halogen atom, —OSO₂—R^{P}, —SO₂—R^{Q} or —S—R^{T}; or a ring structure obtained by combining two or more of these groups. The ring structure may contain heteroatoms such as O and S between the carbon-carbon bonds forming the skeleton. R^{P}, R^{Q} and R^{T} are each independently a substituted or unsubstituted, straight or branched chain alkyl group having a carbon number of 1 to 12; a substituted or unsubstituted alicyclic hydrocarbon group having a carbon number of 5 to 25; and a substituted or unsubstituted aromatic hydrocarbon group having a carbon number of 6 to 12. k1, k2 and k3 are each independently an integer of 0 to 5. When there are a plurality of R^{a1} to R^{a3} and a plurality of R^{P}, R^{Q} and R^{T}, a plurality of R^{a1} to R^{a3} and a plurality of R^{P}, R^{Q} and R^{T} may be each identical or different.

In the formula (X-2), R^{b1} is a substituted or unsubstituted, straight chain or branched alkyl group or alkoxy group having a carbon number of 1 to 20; a substituted or unsubstituted acyl group having a carbon number of 2 to 8; or a substituted or unsubstituted aromatic hydrocarbon group having a carbon number of 6 to 8; or a hydroxy group. nₖ is 0 or 1. When nₖ is 0, k4 is an integer of 0 to 4. When nₖ is 1, k4 is an integer of 0 to 7. When there are a plurality of R^{b1}, a plurality of R^{b1} may be each identical or different. A plurality of R^{b1} may represent a ring structure obtained by combining them. R^{b2} is a substituted or unsubstituted, straight chain or branched alkyl group having a carbon number of 1 to 7; or a substituted or unsubstituted aromatic hydrocarbon group having a carbon number of 6 to 7. L^{C} is a single bond or divalent linking group. k5 is an integer of 0 to 4. When there are a plurality of R^{b2}, a plurality of R^{b2} may be each identical or different. A plurality of R^{b2} may represent a ring structure obtained by combining them. q is an integer of 0 to 3. In the formula, the ring structure containing S⁺ may contain a heteroatom such as O or S between the carbon-carbon bonds forming the skeleton.

In the formula (X-3), R^{c1}, R^{c2} and R^{c3} are each independently a substituted or unsubstituted, straight or branched chain alkyl group having a carbon number of 1 to 12.

In the formula (X-4), R^{g1} is a substituted or unsubstituted linear or branched alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxy group. nₖ is 0 or 1. When nₖ₂ is 0, k10 is an integer of 0 to 4, and when nₖ₂ is 1, k10 is an integer of 0 to 7. When there are two or more R^{g1}s, the two or more R^{g1}s are the same or different from each other, and may represent a cyclic structure formed by combining them together. R^{g2} and R^{g3} are each independently a substituted or unsubstituted linear or branched alkyl, alkoxy, or alkoxycarbonyloxy group having 1 to 12 carbon atoms, a substituted or unsubstituted monocyclic or polycyclic cycloalkyl group having 3 to 12 carbon atoms, a substituted or unsubstituted aromatic hydrocarbon group having 6 to 12 carbon atoms, a hydroxyl group, a halogen atom, or a ring structure formed by combining two or more of these groups together. K11 and k12 are each independently an integer of 0 to 4. When there are two or more R^{g2}s and two or more R^{g3}s, the two or more R^{g2}s may be the same or different from each other, and the two or more R^{g3}s may be the same or different from each other.

In the formula (X-5), R^{d1} and R^{d2} are each independently a substituted or unsubstituted, straight or branched chain alkyl group, alkoxy group or alkoxycarbonyl group having a carbon number of 1 to 12; a substituted or unsubstituted aromatic hydrocarbon group having a carbon number of 6 to 12; a halogen atom; a halogenated alkyl group having a carbon number of 1 to 4; a nitro group; or a ring structure obtained by combining two or more of these groups. k6 and k7 are each independently an integer of 0 to 5. When there are a plurality of R^{d1} and a plurality of R^{d2}, a plurality of R^{d1} and a plurality of R^{d2} may be each identical or different.

Examples of the radiation-sensitive acid generator represented by the formula (K-1) include radiation-sensitive acid generators represented by the following formulas (K-1-1) to (K-1-41) (hereinafter, also referred to as “radiation-sensitive acid generators (1-1) to (1-41)”).

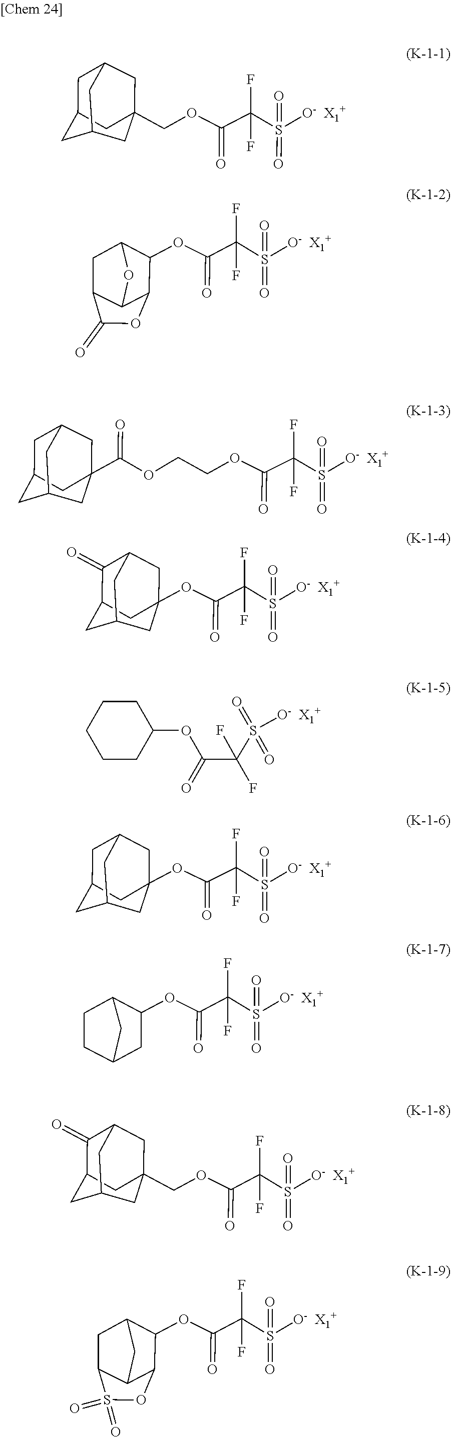

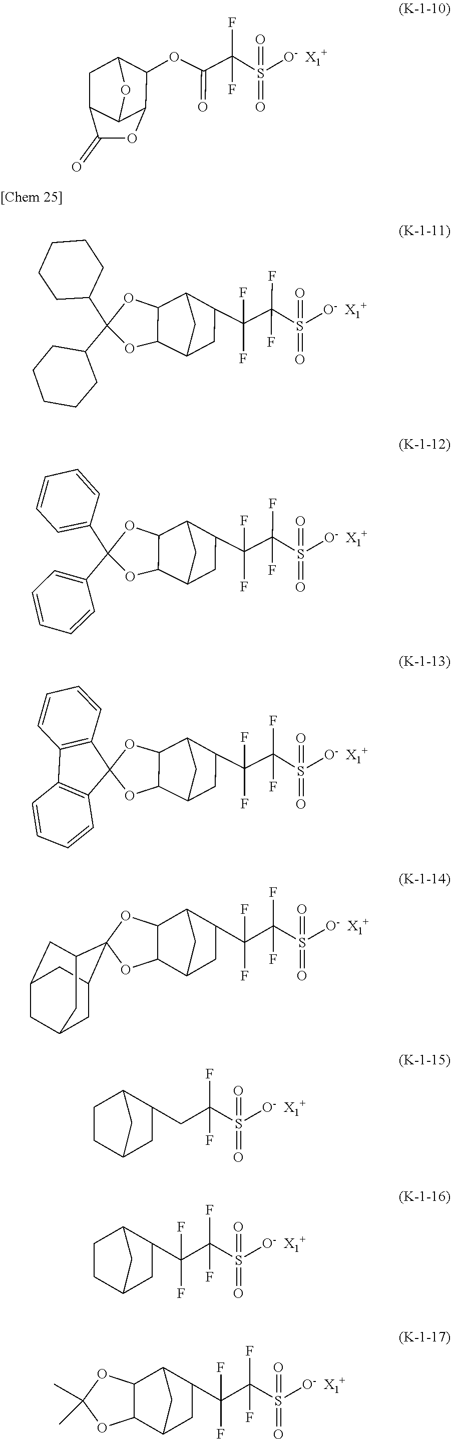

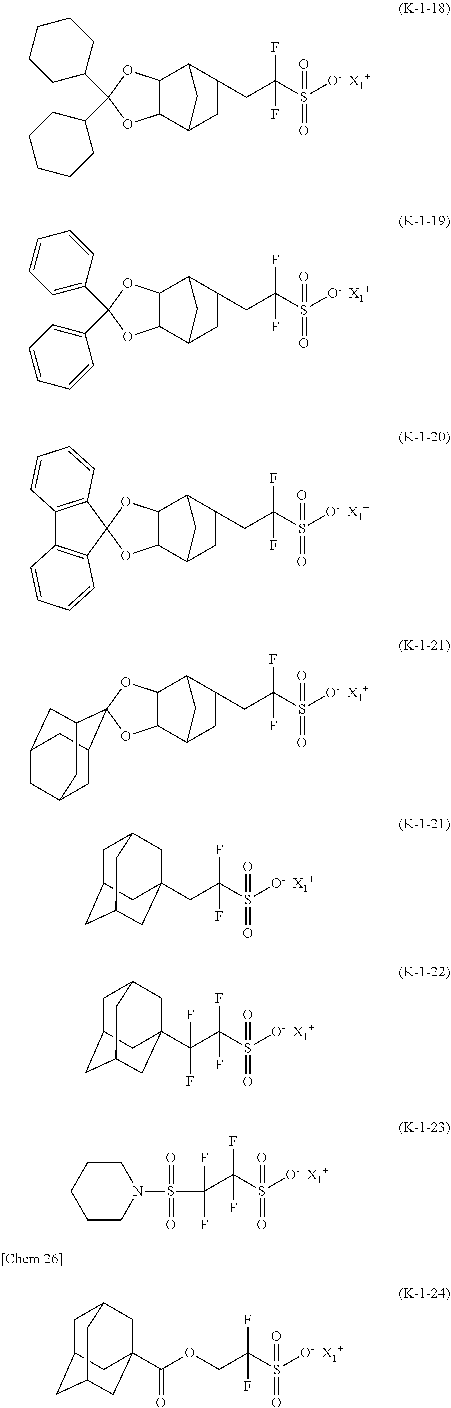

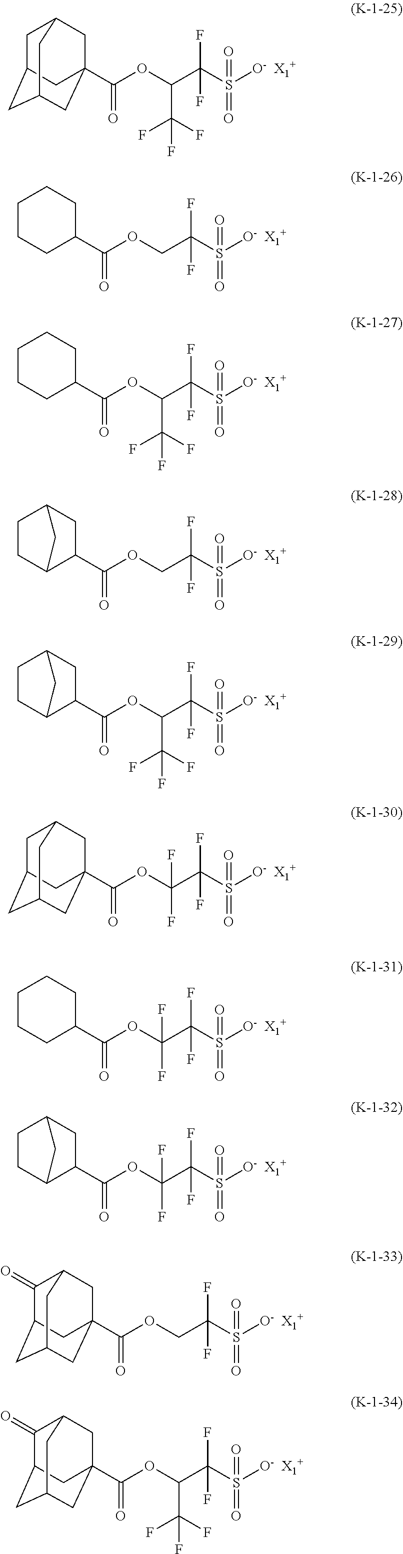

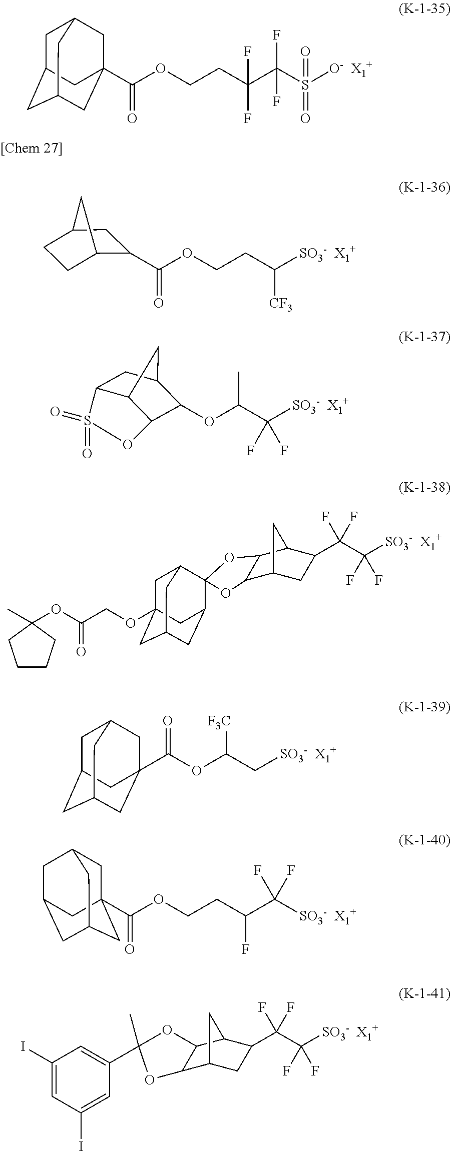

In the formulas (K-1-1) to (K-1-41), X₁⁺ is a monovalent onium cation.

Examples of the radiation-sensitive acid generator also preferably include radiation-sensitive acid generators represented by the following formulas (K-2-1) to (K-2-12) (hereinafter, also referred to as “radiation-sensitive acid generators (2-1) to (2-12)”). X₂⁺ is a monovalent onium cation.

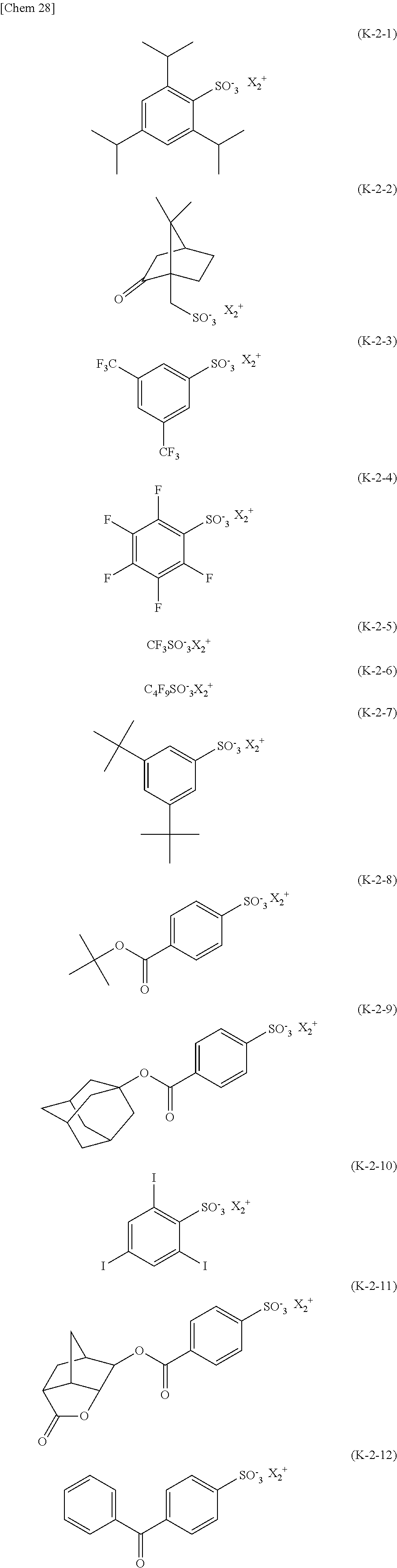

When KrF excimer laser light, EUV, or an electron beam is used as a radioactive ray for irradiation in an exposure step in a method for forming a resist pattern, a sulfonate anion in the radiation-sensitive acid generator preferably has one or more iodine atoms.

The monovalent onium cation represented by X₁⁺ and the monovalent onium cation represented by X₂⁺ preferably have one or more fluorine atoms, and more preferably have 3 or more fluorine atoms. Examples of such an onium cation include cations having the formula (X-1) in which k1=1, k2=k3=0, and R^{a1}=fluorine atom, cations in which k1=k2=k3=1, and R^{a1}═R^{a2}═R^{a3}=fluorine atom, cations in which k1=1, k2=k3=0, and R^{a1}=trifluoromethyl group, cations in which k1=k2=k3=1, R^{a1}═R^{a2}=fluorine atom, and R^{a3}=trifluoromethyl group, and cations in which k1=k2=1, k3=0, and R^{a1}═R^{a2}=trifluoromethyl group.

The radiation-sensitive acid generators may be used singly or in combination of two or more of them. The lower limit of the content of the radiation-sensitive acid generator (when two or more kinds of radiation-sensitive acid generators are present, the content of the radiation-sensitive acid generator content is the total content of the radiation-sensitive acid generators) is preferably 3 parts by mass, more preferably 5 part by mass, even more preferably 10 parts by mass per 100 parts by mass of the resin. The upper limit of the content is preferably 50 parts by mass, more preferably 45 parts by mass, even more preferably 40 parts by mass. This makes it possible to exhibit excellent sensitivity, CDU performance, and resolution during resist pattern formation.

### Acid Diffusion Controlling Agent

If necessary, the radiation-sensitive resin composition may contain an acid diffusion controlling agent. The acid diffusion controlling agent has the effect of controlling a phenomenon in which an acid generated from the radiation-sensitive acid generator by exposure diffuses in a resist film to prevent an undesired chemical reaction in an unexposed part. Further, the radiation-sensitive acid controlling agent improves the storage stability of a resulting radiation-sensitive resin composition. Further, the resolution of a resist pattern is further improved, the line width change of a resist pattern due to variation in post exposure delay time between exposure and development treatment can be prevented, and a radiation-sensitive resin composition excellent in process stability can be obtained.

Examples of acid diffusion controlling agents include nitrogen-containing compounds. Specific examples include primary amine compounds, secondary amine compounds, tertiary amine compounds, imino group-containing compounds, amide group-containing compounds, urea compounds, nitrogen-containing heterocyclic compounds, and the like.

Moreover, a compound having an acid-dissociable group can also be used as the nitrogen-containing organic compound.

As the acid diffusion controlling agent, an onium salt compound may appropriately be used which generates an acid having a pKa higher than that of an acid generated from the above-described radiation-sensitive acid generator (hereinafter, also referred to as a “radiation-sensitive weak acid generator” for the sake of expediency). An acid generated from the radiation-sensitive weak acid generator is a weak acid that does not induce dissociation of the acid-dissociable group under conditions where the acid-dissociable group in the resin is dissociated. It is to be noted that in this description, the term “dissociation” of the acid-dissociable group means that the acid-dissociable group is dissociated by post-exposure bake at 110° C. for 60 seconds.

Examples of the radiation-sensitive weak acid generator include a sulfonium salt compound represented by the following formula (8-1) and a iodonium salt compound represented by the following formula (8-2).

[Chem 29]

J⁺E⁻ (8-1)

U⁺Q⁻ (8-2)

In the above formulas (8-1) and (8-2), J⁺ is a sulfonium cation, and U⁺ is a iodonium cation. Examples of the sulfonium cation represented by J+ include sulfonium cations represented by the above formulas (X-1) to (X-4), and among these, sulfonium cations containing a fluorine-substituted aromatic ring structure are preferred. Examples of the iodonium cation represented by U⁺ include iodonium cations represented by the above formula (X-5), and among these, iodonium cations containing a fluorine-substituted aromatic ring structure are preferred. E⁻ and Q⁻ are each independently an anion represented by OH⁻, R^{αα}—COO⁻, or —N⁻—. R^{αα} is an alkyl group, an aryl group, or an aralkyl group. The hydrogen atom of the alkyl group represented by R^{αα} or the hydrogen atom of aromatic ring of the aryl group or the aralkyl group may be substituted by a halogen atom, a hydroxyl group, a nitro group, a halogen atom-substituted or unsubstituted alkyl group having 1 to 12 carbon atoms, or a halogen atom-substituted or unsubstituted alkoxy group having 1 to 12 carbon atoms.

Examples of the radiation-sensitive weak acid generator include compounds represented by the following formulas.

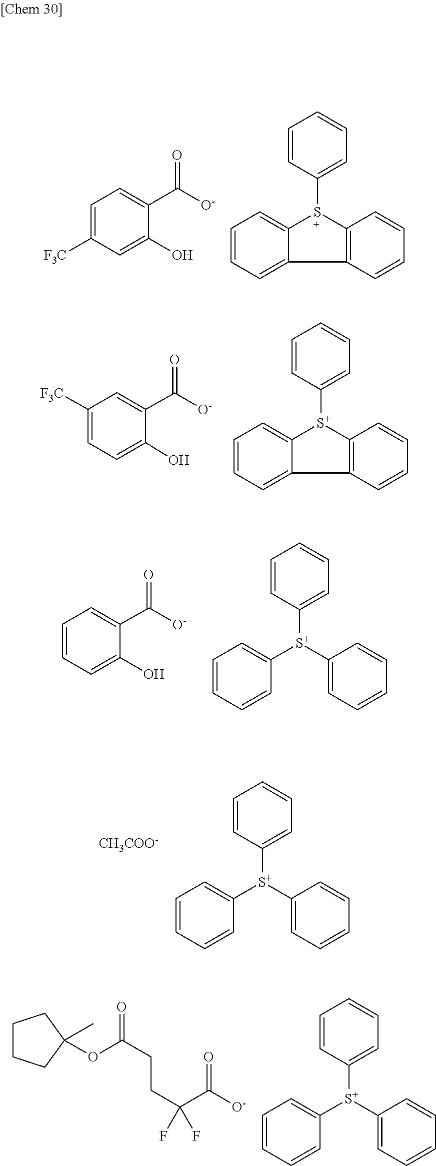

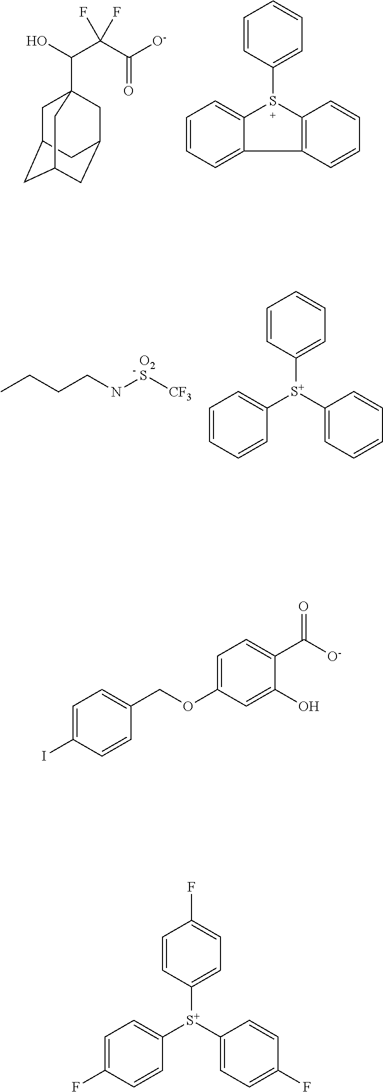

The lower limit of the content of the acid diffusion controlling agent is preferably 5 mol %, more preferably 10 mol %, even more preferably 15 mol % with respect to the total number of moles of the radiation-sensitive acid generator. The upper limit of the content is preferably 60 mol %, more preferably 55 mol %, even more preferably 50 mol %. When the content of the acid diffusion controlling agent is set to fall within the above range, the lithography performance of the radiation-sensitive resin composition can further be improved. The radiation-sensitive resin composition may contain one or two or more kinds of acid diffusion controlling agents.

### <Solvent>

The radiation-sensitive resin composition according to the present embodiment contains a solvent. The solvent is not particularly limited as long as it is a solvent capable of dissolving or dispersing at least the resin, the radiation-sensitive acid generator, and additives or the like contained as desired.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
a monoalcohol-based solvent having a carbon number of 1 to 18, including iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
a polyhydric alcohol having a carbon number of 2 to 18, including ethylene glycol, 1,2-propylene glycol, 2-methyl-2,4-pentanediol, 2,5-hexanediol, diethylene glycol, dipropylene glycol, triethylene glycol, and tripropylene glycol; and a partially etherized polyhydric alcohol-based solvent in which a part of hydroxy groups in the polyhydric alcohol-based solvent is etherized.

Examples of the ether-based solvent include:
a dialkyl ether-based solvent, including diethyl ether, dipropyl ether, and dibutyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized.

Examples of the ketone-based solvent include:
a chain ketone-based solvent, including acetone, butanone, and methyl-iso-butyl ketone;
a cyclic ketone-based solvent, including cyclopentanone, cyclohexanone, and methylcyclohexanone; and 2,4-pentanedione, acetonylacetone, and acetophenone.

Examples of the amide-based solvent include:
a cyclic amide-based solvent, including N,N′-dimethyl imidazolidinone and N-methylpyrrolidone; and
a chain amide-based solvent, including N-methylformamide, N,N-dimethylformamide, N,N-diethylformamide, acetamide, N-methylacetamide, N,N-dimethylacetamide, and N-methylpropionamide.

Examples of the ester-based solvent include:
a monocarboxylate ester-based solvent, including n-butyl acetate and ethyl lactate;
a partially etherized polyhydric alcohol acetate-based solvent, including diethylene glycol mono-n-butyl ether acetate, propylene glycol monomethyl ether acetate, and dipropylene glycol monomethyl ether acetate;
a lactone-based solvent, including γ-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, ethyl lactate, and diethyl phthalate.

Examples of the hydrocarbon-based solvent include:
an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

Among them, the ester-based solvent or the ketone-based solvent is preferred. The partially etherized polyhydric alcohol-based solvent, the partially etherized polyhydric alcohol acetate-based solvent, the cyclic ketone-based solvent, or the lactone-based solvent is more preferred. Propylene glycol monomethyl ether, propylene glycol monomethyl ether acetate, cyclohexanone, or γ-butyrolactone is still more preferred. The radiation-sensitive resin composition may include one type of the solvent, or two or more types of the solvents in combination.

### <Other Optional Components>

The radiation-sensitive resin composition may contain other optional components other than the above-descried components. Examples of other optional components include a cross-linking agent, a localization enhancing agent, a surfactant, an alicyclic backbone-containing compound, and a sensitizer. These other optional components may be used singly or in combination of two or more of them.

### <Method for Preparing Radiation-Sensitive Resin Composition>

The radiation-sensitive resin composition can be prepared, for example, by mixing the resin, the radiation-sensitive acid generator, and the solvent with any other components as necessary at a predetermined ratio. The radiation-sensitive resin composition is preferably filtered through, for example, a filter having a pore diameter of about 0.05 μm after mixing. The solid matter concentration of the radiation-sensitive resin composition is usually 0.1 mass % to 50 mass %, preferably 0.5 mass % to 30 mass %, more preferably 1 mass % to 20 mass %.

### <<Resin>>

The resin according to the embodiment contains a structural unit (I) represented by the following formula (1).

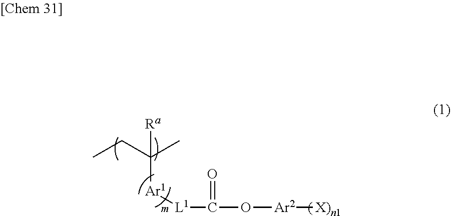

(In the formula (1),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on the Ar¹ side,
Ar² is a substituted or unsubstituted monovalent aromatic hydrocarbon group having 6 to 20 carbon atoms,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 to (the number of hydrogen atoms in the monovalent aromatic hydrocarbon group represented by the Ar²).

As the resin, the resin in the radiation-sensitive resin composition can be suitably employed. When the radiation-sensitive resin composition contains the resin, the sensitivity, CDU performance, and resolution of the resist film can be improved.

### <<Compound>>

The compound according to the embodiment is represented by the following formula (i).

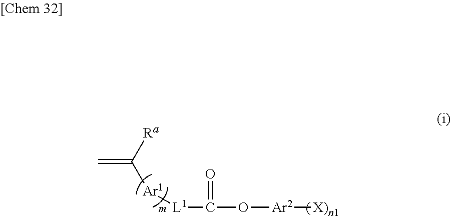

(In the formula (i),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on the Ar¹ side,
Ar² is a substituted or unsubstituted monovalent aromatic hydrocarbon group having 6 to 20 carbon atoms,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 to (the number of hydrogen atoms in the monovalent aromatic hydrocarbon group represented by the Ar²).

The same configuration as that of the structural unit (I) of the resin in the radiation-sensitive resin composition can be suitably employed for the compound, which can be suitably used as a monomer compound that provides the structural unit (I) of the resin.

### <Method for Forming Pattern>

A method for forming a pattern according to an embodiment of the present invention includes:
(1) applying the radiation-sensitive resin composition directly or indirectly on a substrate to form a resist film (hereinafter, also referred to as a “resist film forming step”);
(2) exposing the resist film (hereinafter, also referred to as an “exposure step”); and
(3) developing the exposed resist film (hereinafter, also referred to as a “developing step”).

The method for forming a pattern uses the above-described radiation-sensitive resin composition excellent in sensitivity in the exposure step, CDU performance, and resolution, and therefore a high-quality resist pattern can be formed. Hereinbelow, each of the steps will be described.

### Resist Film Forming Step

In this step (the above mentioned step (1)), a resist film is formed with the radiation-sensitive resin composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60° C. to 140° C., and preferably from 80° C. to 120° C. The duration of PB is typically from 5 seconds to 600 seconds, and preferably from 10 seconds to 300 seconds. The thickness of the resist film formed is preferably from 10 nm to 1,000 nm, and more preferably from 10 nm to 500 nm.

When the next step, the exposure step, is performed with radiation having a wavelength of 50 nm or less, it is preferable to use a resin having the structural unit (III) and, if necessary, the structural unit (II) as the base resin in the composition.

### Exposing Step

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and γ ray; an electron beam; and a charged particle radiation such as α ray. Among them, far ultraviolet ray, an electron beam, or EUV is preferred. ArF excimer laser light (wavelength is 193 nm), KrF excimer laser light (wavelength is 248 nm), an electron beam, or EUV is more preferred. An electron beam or EUV having a wavelength of 50 nm or less which is identified as the next generation exposing technology is further preferred.

After the exposure, post exposure bake (PEB) is preferably carried out to promote the dissociation of the acid-dissociable group in the resin by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

### Developing Step

In this step (the above mentioned step (3)), the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive resin composition. Among them, an ester-based solvent or a ketone-based solvent is preferred. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably not less than 80% by mass, more preferably not less than 90% by mass, further preferably not less than 95% by mass, and particularly preferably not less than 99% by mass. Examples of the ingredient other than the organic solvent in the developer include water and silicone oil.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### EXAMPLES

Hereinafter, the present invention will be specifically described with reference to Examples, but the present invention is not limited to these Examples. Methods for measuring various property values are shown below. In the polymerization reaction in the following synthesis examples, unless otherwise specified, parts by mass means a value taken when the total mass of monomers used is 100 parts by mass, and mol % means a value taken when the total number of moles of monomers used is 100 mol %.

### [Measurement of Weight Average Molecular Weight (Mw), Number Average Molecular Weight (Mn), and Dispersity (Mw/Mn)]

Measurement was performed under the measurement conditions described in the section of Resin. The polydispersity (Mw/Mn) was calculated from the measurement results of Mw and Mn.

[¹H-NMR Analysis and ¹³C-NMR Analysis]

Measurement was performed with use of “JNM-Delta 400” manufactured by JEOL Ltd.

### <[Z] Synthesis of Monomer Compound>

### Synthesis Example 1: Synthesis of Compound (Z-1)

A Compound (Z-1) was synthesized according to the following reaction scheme.

Chloroacetyl chloride (135 mmol) and pyridine (162 mmol) were added to a vessel containing tetrahydrofuran (135 mL), and the mixture was cooled to 0° C. To this vessel, a solution of 4-iodophenol (135 mmol) in tetrahydrofuran (135 mL) was added dropwise over 1 hour. After completion of the dropwise addition, the mixture was further stirred at room temperature for 6 hours. After cooling to 10° C. or lower, a saturated aqueous sodium bicarbonate solution (100 mL) was added to stop the reaction. After extraction with ethyl acetate, the organic layer was washed with brine and then ultrapure water. The organic layer was dried over sodium sulfate and then filtered. The solvent was distilled off to yield a Compound (P-1).

The Compound (P-1) (50 mmol) was added to a container containing N,N-dimethylformamide (120 mL), and the mixture was cooled to 0° C. To this container, methacrylic acid (75 mmol) and potassium carbonate (100 mmol) were added. The mixture was stirred at 60° C. for 3 hours, and then diluted by adding ethyl acetate. Subsequently, potassium carbonate was removed by Celite filtration. The organic layer was washed with a saturated aqueous ammonium chloride solution, brine, and ultrapure water in this order. The organic layer was dried over sodium sulfate and then filtered. The solvent was distilled off to yield a Compound (Z-1).

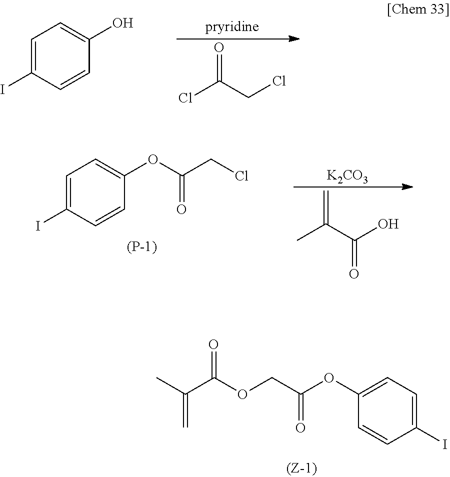

### Synthesis Examples 2 to 11: Synthesis of Compounds (Z-2) to (Z-11)

Compounds (Z-2) to (Z-11) represented by the following formulae (Z-2) to (Z-11) were synthesized by appropriately selecting a precursor and selecting the same formulation as that of Synthesis Example 1.

### Reference Examples 1 to 2: Synthesis of Compounds (W-1) to (W-2)

Compounds (W-1) to (W-2) were synthesized with reference to JP-A-2019-001997 for the compound represented by the following formula (W-1), and with reference to JP-A-2012-048067 for the compound represented by the following formula (W-2), respectively.

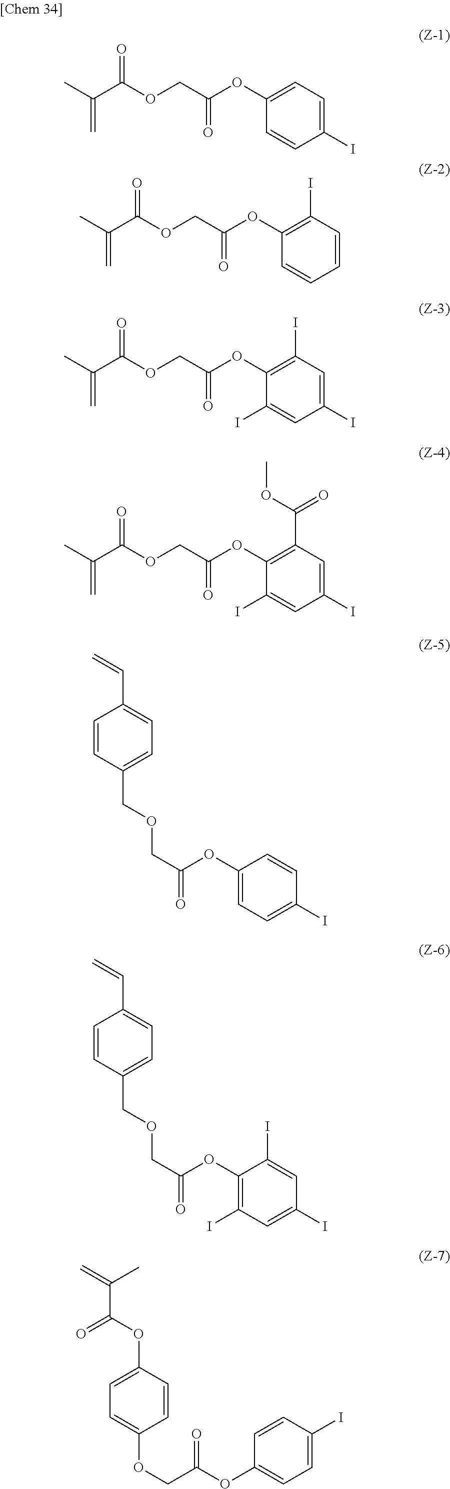

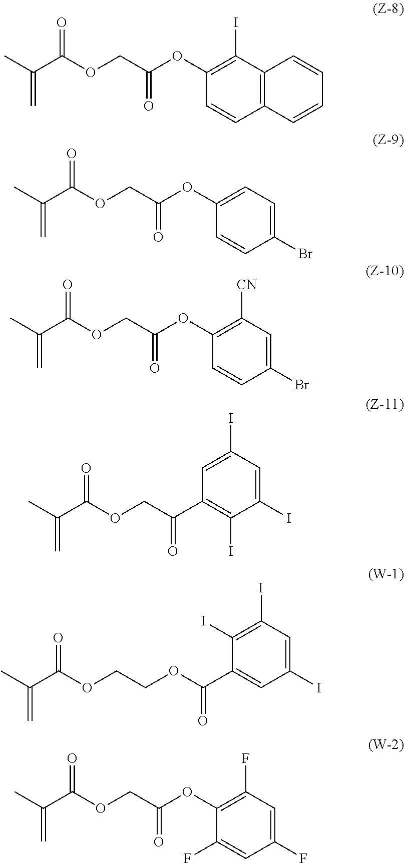

### <[A] Synthesis of Resin as Base Resin>

Monomer compounds used for synthesis of the respective resins as base resins in the respective Examples and Comparative Examples are shown below. In the following synthesis examples, unless otherwise specified, “parts by mass” means a value taken when the total mass of the monomers used is 100 parts by mass, and “mol %” means a value taken when the total number of moles of the monomers used is 100 mol %.

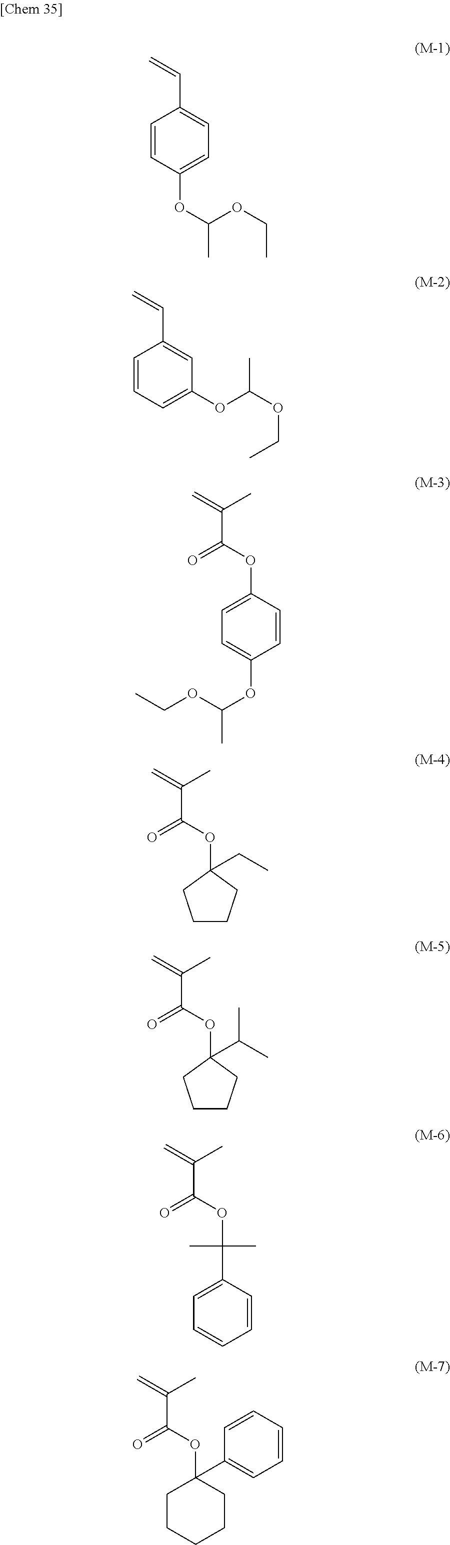

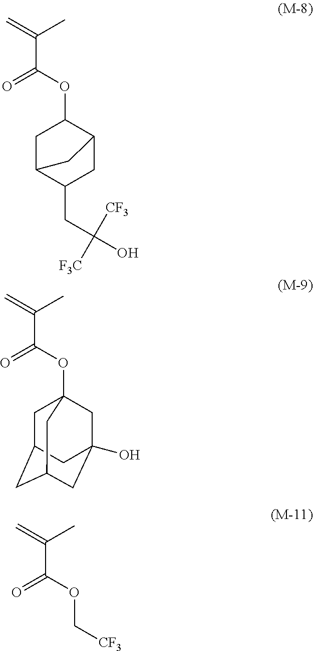

### Resin Synthesis Example 1: Synthesis of Resin (A-1)

Compounds (M-1), (M-4) and (Z-1) were dissolved in 1,4-dioxane (200 parts by mass with respect to the total amount of monomers) so as to have a molar ratio of 35/45/20. Next, azobisisobutyronitrile was added as an initiator in an amount of 6 mol % with respect to all the monomers to prepare a monomer solution.

On the other hand, 1,4-dioxane (100 parts by mass with respect to the total amount of monomers) was added to an empty container, and then heated to 82° C. with stirring. The monomer solution prepared as described above was added dropwise to the container over 1 hour. After completion of the dropwise addition, the mixture was further stirred at 82° C. for 6 hours, and then the reaction solution was cooled to room temperature. The obtained reaction solution was poured into a mixed solution of methanol/ion-exchanged water=3/1 (mass ratio) (2,000 parts by mass) for reprecipitation. The resin obtained after filtration was dissolved in methyl isobutyl ketone (300 parts by mass), and to this solution, a solution obtained by dissolving p-toluenesulfonic acid (1.5 parts by mass) in ion-exchanged water (150 parts by mass) was added, followed by stirring for 6 hours.

After liquid separation performed by using a separatory funnel, the organic layer was washed three times with ion-exchanged water. A polymer obtained by concentrating and drying the organic layer was dissolved in acetone (150 parts by mass). The solution was added dropwise to water (2,000 parts by mass) for solidification. The generated white powder was separated by filtration. The resultant was dried at 50° C. for 17 hours to give a white powdery Resin (A-1) in good yield.

### Resin Synthesis Examples 2 to 22: Synthesis of Resins (A-2) to (A-23)

Resins (A-2) to (A-23) were synthesized by appropriately selecting monomers and performing the same operations as in Resin Synthesis Example 1.

The used amounts of the respective structural units, the values of Mw and Mw/Mn of the obtained resins are shown together in Table 1. In Table 1, the portion represented by “-” indicates that a corresponding component was not used. The same applies to the following tables.

TABLE 1

| | | Monomer that | | Monomer that | | | | | | | |
|---|---|---|---|---|---|---|---|---|---|---|---|
| | | gives | | gives | | Monomer that | | | | | |
| | | structural unit | | structural unit | | gives structural | | Monomer that | | | |
| | | (I) | | (II) | | unit (III) | | gives structural | | | |
| | | | Used | | Used | | Used | unit (IV) | | | |
| | [A] | | amount | | amount | | amount | | Used amount | | |
| | Resin | Type | (mol %) | Type | (mol %) | Type | (mol %) | Type | (mol %) | Mw | Mw/Mn |
| Resin Synthesis | A-1 | Z-1 | 20 | M-1 | 35 | M-4 | 45 | — | — | 6,000 | 1.6 |
| Example 1 | | | | | | | | | | | |
| Resin Synthesis | A-2 | Z-1 | 10 | M-1 | 45 | M-4 | 45 | — | — | 6,200 | 1.5 |
| Example 2 | | | | | | | | | | | |
| Resin Synthesis | A-3 | Z-1 | 5 | M-1 | 50 | M-4 | 45 | — | — | 6,400 | 1.5 |
| Example 3 | | | | | | | | | | | |
| Resin Synthesis | A-4 | Z-2 | 10 | M-1 | 45 | M-4 | 45 | — | — | 5,800 | 1.5 |
| Example 4 | | | | | | | | | | | |
| Resin Synthesis | A-5 | Z-3 | 10 | M-1 | 45 | M-4 | 45 | — | — | 5,900 | 1.5 |
| Example 5 | | | | | | | | | | | |
| Resin Synthesis | A-6 | Z-4 | 10 | M-1 | 45 | M-4 | 45 | — | — | 5,500 | 1.6 |
| Example 6 | | | | | | | | | | | |
| Resin Synthesis | A-7 | Z-5 | 10 | M-1 | 45 | M-4 | 45 | — | — | 6,700 | 1.7 |
| Example 7 | | | | | | | | | | | |
| Resin Synthesis | A-8 | Z-6 | 10 | M-1 | 45 | M-4 | 45 | — | — | 4,300 | 1.6 |
| Example 8 | | | | | | | | | | | |
| Resin Synthesis | A-9 | Z-7 | 10 | M-1 | 45 | M-4 | 45 | — | — | 5,000 | 1.4 |
| Example 9 | | | | | | | | | | | |
| Resin Synthesis | A-10 | Z-8 | 10 | M-1 | 45 | M-4 | 45 | — | — | 7,000 | 1.6 |
| Example 10 | | | | | | | | | | | |
| Resin Synthesis | A-11 | Z-9 | 10 | M-1 | 45 | M-4 | 45 | — | — | 5,800 | 1.7 |
| Example 11 | | | | | | | | | | | |
| Resin Synthesis | A-12 | Z-10 | 10 | M-1 | 45 | M-4 | 45 | — | — | 5,900 | 1.6 |
| Example 12 | | | | | | | | | | | |
| Resin Synthesis | A-13 | Z-11 | 10 | M-1 | 45 | M-4 | 46 | — | — | 5,800 | 1.6 |
| Example 13 | | | | | | | | | | | |
| Resin Synthesis | A-14 | Z-1 | 10 | M-2 | 45 | M-4 | 45 | — | — | 6,100 | 1.7 |
| Example 14 | | | | | | | | | | | |
| Resin Synthesis | A-15 | Z-1 | 10 | M-3 | 45 | M-4 | 45 | — | — | 5,700 | 1.5 |
| Example 15 | | | | | | | | | | | |
| Resin Synthesis | A-16 | Z-1 | 10 | M-1 | 45 | M-5 | 45 | — | — | 5,500 | 1.6 |
| Example 16 | | | | | | | | | | | |
| Resin Synthesis | A-17 | Z-1 | 10 | M-1 | 45 | M-6 | 45 | — | — | 6,700 | 1.5 |
| Example 17 | | | | | | | | | | | |
| Resin Synthesis | A-18 | Z-1 | 10 | M-1 | 45 | M-7 | 45 | — | — | 6,800 | 1.6 |
| Example 18 | | | | | | | | | | | |
| Resin Synthesis | A-19 | Z-1 | 10 | M-1 | 35 | M-4 | 45 | M-8 | 10 | 7,000 | 1.6 |
| Example 19 | | | | | | | | | | | |
| Resin Synthesis | A-20 | Z-1 | 10 | M-1 | 35 | M-4 | 45 | M-9 | 10 | 4,800 | 1.6 |
| Example 20 | | | | | | | | | | | |
| Resin Synthesis | A-21 | W-1 | 10 | M-1 | 45 | M-4 | 45 | — | — | 6,000 | 1.6 |
| Example 21 | | | | | | | | | | | |
| Resin Synthesis | A-22 | W-2 | 10 | M-1 | 45 | M-4 | 45 | — | — | 5,600 | 1.6 |
| Example 22 | | | | | | | | | | | |
| Resin Synthesis | A-23 | — | — | M-1 | 55 | M-4 | 45 | — | — | 5,800 | 1.7 |
| Example 23 | | | | | | | | | | | |

### Resin Synthesis Example 24: Synthesis of High Fluorine-Content Resin (B-1)

Compounds (M-4) and (M-11) were dissolved in 2-butanone (100 parts by mass with respect to the total amount of monomers) so as to have a molar ratio of 30/70. To this, azobisisobutyronitrile (5 mol % with respect to the total amount of monomers) was added as an initiator to prepare a monomer solution.

On the other hand, 2-butanone (50 parts by mass) was placed in an empty container, followed by purge with nitrogen for 30 minutes. The inside of the container was heated to 80° C., and the monomer solution was added dropwise thereto over 3 hours with stirring. After completion of the dropwise addition, the mixture was further heated at 80° C. for 3 hours, and then the polymerization solution was cooled to 30° C. or lower. The polymerization solution was transferred to a separatory funnel, followed by addition of hexane (150 parts by mass) to dilute the polymerization solution uniformly. Methanol (600 parts by mass) and water (30 parts by mass) were further charged, followed by mixing. After standing for 30 minutes, the lower layer was collected, and the solvent was replaced with propylene glycol monomethyl ether acetate. In this way, a 10% solution of the high fluorine-content resin (B-1) in propylene glycol monomethyl ether acetate was obtained.

### Resin Synthesis Examples 25 to 27: Synthesis of High Fluorine-Content Resins (B-2) to (B-4)

High fluorine-content Resins (B-2) to (B-4) were synthesized by appropriately selecting monomers and performing the same operations as in Resin Synthesis Example 23.

The used amounts of the respective structural units in the obtained polymer are shown together in Table 2.

TABLE 2

| | | Monomer that | | Monomer that | | Monomer that | | Monomer that | |
|---|---|---|---|---|---|---|---|---|---|
| | | gives structural | | gives structural | | gives structural | | gives another | |
| | [B] High | unit (I) | | unit (III) | | unit (IV) | | structural unit | |
| | fluorine- | | Used | | Used | | Used | | Used |
| | content | | amount | | amount | | amount | | amount |
| | resin | Type | (mol %) | Type | (mol %) | Type | (mol %) | Type | (mol %) |
| Resin Synthesis | B-1 | — | — | M-4 | 30 | M-11 | 70 | — | — |
| Example 24 | | | | | | | | | |
| Resin Synthesis | B-2 | Z-1 | 10 | M-4 | 30 | M-11 | 60 | — | — |
| Example 25 | | | | | | | | | |
| Resin Synthesis | B-3 | — | — | M-4 | 30 | M-11 | 60 | W-1 | 10 |
| Example 26 | | | | | | | | | |
| Resin Synthesis | B-4 | — | — | M-4 | 30 | M-11 | 60 | W-2 | 10 |
| Example 27 | | | | | | | | | |

### <Preparation of Radiation-Sensitive Resin Composition>

Radiation-sensitive acid generators [C], acid diffusion controlling agents [D], and solvents [E] used for the preparation of the radiation-sensitive resin compositions of the following Examples and Comparative Examples are shown below.

### [C] Radiation-Sensitive Acid Generator

Compounds represented by (C-1) to (C-9) were used as radiation-sensitive acid generators.

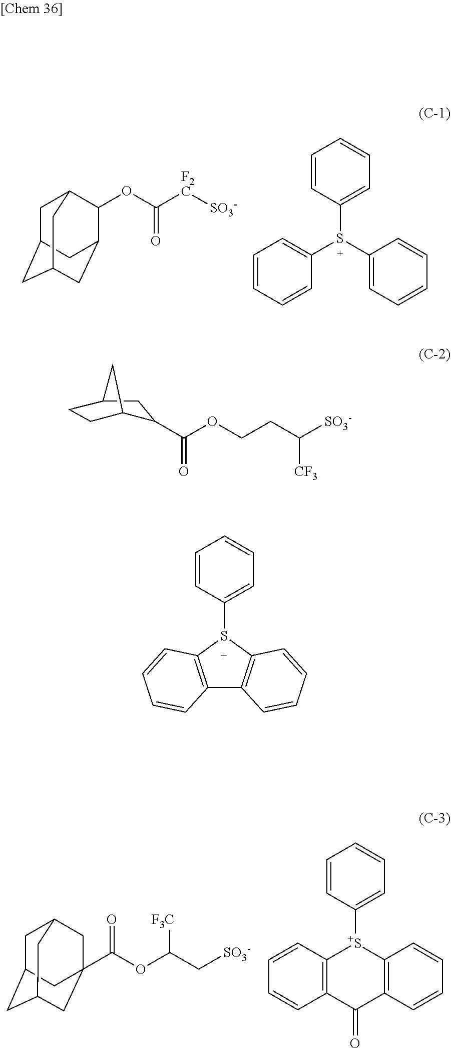

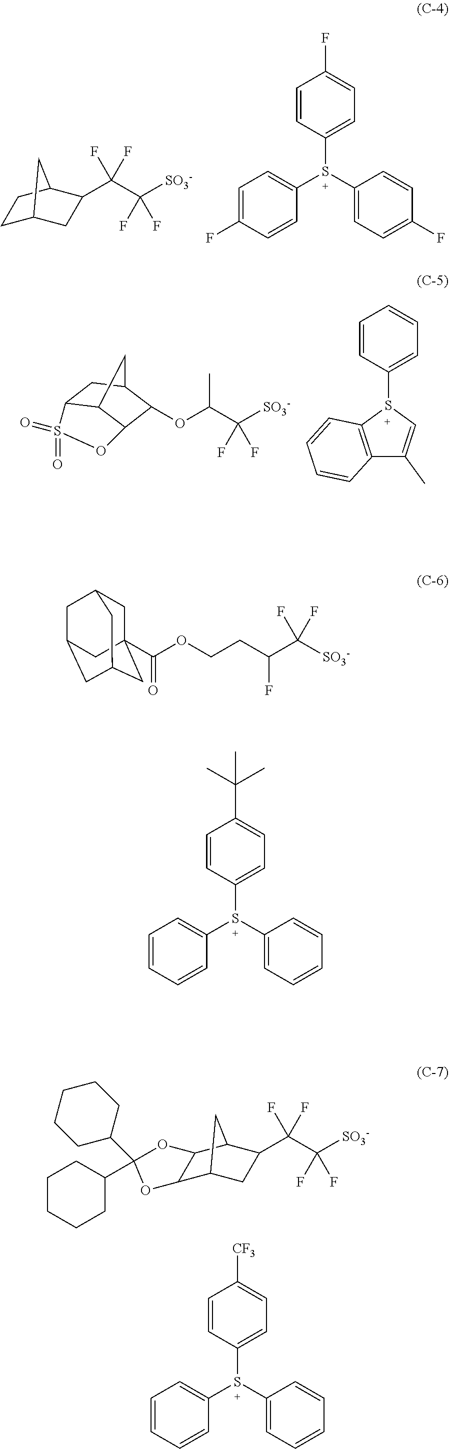

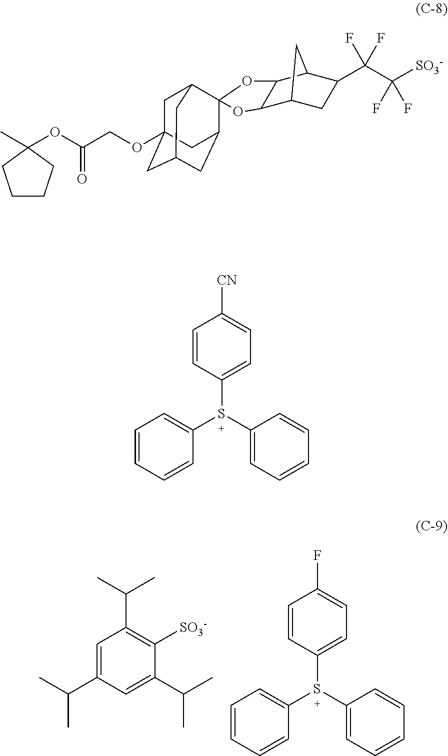

### [D] Acid Diffusion Controlling Agent

As the acid diffusion controlling agent, a compound represented by (D-1) was used.

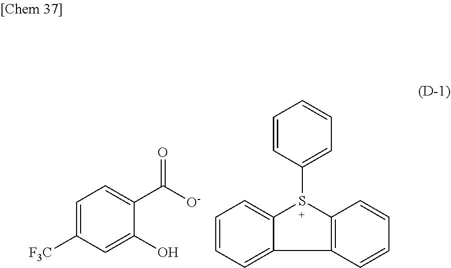

### [E] Solvent

E-1: Propylene glycol monomethyl ether acetate
E-2: Propylene glycol monomethyl ether

### Example 1

A radiation-sensitive resin composition (R-1) was prepared by blending 100 parts by mass of the resin (A-1) [A], 3 parts by mass of the high fluorine-content resin (B-1) [B] in terms of solid content, 22 parts by mass of (C-1) as the acid generator [C], 40 mol % of (D-1) as the acid diffusion controlling agent [D] with respect to (C-1), and (E-1) and (E-2) as the solvent [E].

### Examples 2 to 29 and Comparative Examples 1 to 4

Radiation-sensitive resin compositions (R-2) to (R-29) and (CR-1) to (CR-4) were prepared in the same manner as in Example 1 except that the respective components of the types and the blending amounts shown in the following Table 3 were used.

TABLE 3

| | | | | | | [C] Radiation- | | | | | |
|---|---|---|---|---|---|---|---|---|---|---|---|
| | | | | [B] High fluorine- | | sensitive acid | | | | | |
| | Radiation- | [A] Resin | | content resin | | generator | | [D] Acid diffusion | | [E] Solvent | |
| | sensitive | | Content | | Content | | Content | controlling agent | | | Content |
| | resin | | (parts by | | (parts by | | (parts by | | Content | | (parts by |
| | composition | Type | mass) | Type | mass) | Type | mass) | Type | (mol %) | Type | mass) |
| Example 1 | R-1 | A-1 | 100 | B-1 | 3 | C-1 | 22 | D-1 | 40 | E-1/E-2 | 5500/1500 |
| Example 2 | R-2 | A-2 | 100 | B-1 | 3 | C-1 | 22 | D-1 | 40 | E-1/E-2 | 5500/1500 |
| Example 3 | R-3 | A-3 | 100 | B-1 | 3 | C-1 | 22 | D-1 | 40 | E-1/E-2 | 5500/1500 |
| Example 4 | R-4 | A-4 | 100 | B-1 | 3 | C-1 | 22 | D-1 | 40 | E-1/E-2 | 5500/1500 |
| Example 5 | R-5 | A-5 | 100 | B-1 | 3 | C-1 | 22 | D-1 | 40 | E-1/E-2 | 5500/1500 |
| Example 6 | R-6 | A-6 | 100 | B-1 | 3 | C-1 | 22 | D-1 | 40 | E-1/E-2 | 5500/1500 |
| Example 7 | R-7 | A-7 | 100 | B-1 | 3 | C-1 | 22 | D-1 | 40 | E-1/E-2 | 5500/1500 |
| Example 8 | R-8 | A-8 | 100 | B-1 | 3 | C-1 | 22 | D-1 | 40 | E-1/E-2 | 5500/1500 |
| Example 9 | R-9 | A-9 | 100 | B-1 | 3 | C-1 | 22 | D-1 | 40 | E-1/E-2 | 5500/1500 |
| Example 10 | R-10 | A-10 | 100 | B-1 | 3 | C-1 | 22 | D-1 | 40 | E-1/E-2 | 5500/1500 |
| Example 11 | R-11 | A-11 | 100 | B-1 | 3 | C-1 | 22 | D-1 | 40 | E-1/E-2 | 5500/1500 |
| Example 12 | R-12 | A-12 | 100 | B-1 | 3 | C-1 | 22 | D-1 | 40 | E-1/E-2 | 5500/1500 |
| Example 13 | R-13 | A-13 | 100 | B-1 | 3 | C-1 | 22 | D-1 | 40 | E-1/E-2 | 5500/1500 |
| Example 14 | R-14 | A-14 | 100 | B-1 | 3 | C-1 | 22 | D-1 | 40 | E-1/E-2 | 5500/1500 |
| Example 15 | R-15 | A-15 | 100 | B-1 | 3 | C-1 | 22 | D-1 | 40 | E-1/E-2 | 5500/1500 |
| Example 16 | R-16 | A-16 | 100 | B-1 | 3 | C-1 | 22 | D-1 | 40 | E-1/E-2 | 5500/1500 |
| Example 17 | R-17 | A-17 | 100 | B-1 | 3 | C-1 | 22 | D-1 | 40 | E-1/E-2 | 5500/1500 |
| Example 18 | R-18 | A-18 | 100 | B-1 | 3 | C-1 | 22 | D-1 | 40 | E-1/E-2 | 5500/1500 |
| Example 19 | R-19 | A-19 | 100 | B-1 | 3 | C-1 | 22 | D-1 | 40 | E-1/E-2 | 5500/1500 |
| Example 20 | R-20 | A-20 | 100 | B-1 | 3 | C-1 | 22 | D-1 | 40 | E-1/E-2 | 5500/1500 |
| Example 21 | R-21 | A-2 | 100 | B-2 | 3 | C-1 | 22 | D-1 | 40 | E-1/E-2 | 5500/1500 |
| Example 22 | R-22 | A-2 | 100 | B-1 | 3 | C-2 | 22 | D-1 | 40 | E-1/E-2 | 5500/1500 |
| Example 23 | R-23 | A-2 | 100 | B-1 | 3 | C-3 | 22 | D-1 | 40 | E-1/E-2 | 5500/1500 |
| Example 24 | R-24 | A-2 | 100 | B-1 | 3 | C-4 | 22 | D-1 | 40 | E-1/E-2 | 5500/1500 |
| Example 25 | R-25 | A-2 | 100 | B-1 | 3 | C-5 | 22 | D-1 | 40 | E-1/E-2 | 5500/1500 |
| Example 26 | R-26 | A-2 | 100 | B-1 | 3 | C-6 | 22 | D-1 | 40 | E-1/E-2 | 5500/1500 |
| Example 27 | R-27 | A-2 | 100 | B-1 | 3 | C-7 | 22 | D-1 | 40 | E-1/E-2 | 5500/1500 |
| Example 28 | R-28 | A-2 | 100 | B-1 | 3 | C-8 | 22 | D-1 | 40 | E-1/E-2 | 5500/1500 |
| Example 29 | R-29 | A-2 | 100 | B-1 | 3 | C-9 | 22 | D-1 | 40 | E-1/E-2 | 5500/1500 |
| Comparative | CR-1 | A-21 | 100 | B-1 | 3 | C-1 | 22 | D-1 | 40 | E-1/E-2 | 5500/1500 |
| Example 1 | | | | | | | | | | | |
| Comparative | CR-2 | A-22 | 100 | B-1 | 3 | C-1 | 22 | D-1 | 40 | E-1/E-2 | 5500/1500 |
| Example 2 | | | | | | | | | | | |
| Comparative | CR-3 | A-23 | 100 | B-3 | 3 | C-1 | 22 | D-1 | 40 | E-1/E-2 | 5500/1500 |
| Example 3 | | | | | | | | | | | |
| Comparative | CR-4 | A-23 | 100 | B-4 | 3 | C-1 | 22 | D-1 | 40 | E-1/E-2 | 5500/1500 |
| Example 4 | | | | | | | | | | | |

### <Formation of Resist Pattern>

Each of the radiation-sensitive resin compositions prepared as described above was applied using a spin coater (CLEAN TRACK ACT12, manufactured by Tokyo Electron Ltd.) to a surface of a 12-inch silicon wafer with a 20 nm thick underlayer film (AL412, manufactured by Brewer Science). SB (Soft baking) was performed at 100° C. for 60 seconds, followed by cooling at 23° C. for 30 seconds, to form a resist film having a thickness of 30 nm. Then, the resist film was irradiated with EUV light using an EUV exposure machine (type “NXE3300”, manufactured by ASML, NA=0.33, illumination condition: Conventional, s=0.89). Then, the resist film was subjected to PEB (post exposure baking) at 100° C. for 60 seconds. Then, development was performed at 23° C. for 30 seconds using a 2.38 wt % aqueous tetramethylammonium hydroxide (TMAH) solution to form a positive 50 nm pitch and 25 nm contact hole pattern.

### <Evaluation>

The sensitivity, CDU performance, and resolution of each of the radiation-sensitive resin compositions were evaluated by measuring each of the formed resist patterns according to the following method. A scanning electron microscope (“CG-5000” manufactured by Hitachi High-Tech Corporation) was used for measuring the length of the resist pattern. The evaluation results are shown in Table 4.

### [Sensitivity]

An exposure amount at which the 25 nm contact hole pattern was formed in the formation of the resist pattern was defined as an optimum exposure amount, and the optimum exposure amount was defined as sensitivity (mJ/cm²). When the optimum exposure amount was 65 mJ/cm² or less, the sensitivity was determined as “good”, and the optimum exposure amount exceeded 65 mJ/cm², the sensitivity was determined as “poor”.

### [CDU Performance]

The 25 nm contact hole pattern was observed from above using the scanning electron microscope, and a total of 800 arbitrary points were measured for the length. The dimensional variation (3σ) was determined and taken as the CDU performance (nm). A smaller value of CDU indicates smaller variation in the hole diameter in the long period and better performance. When the value was 4.0 nm or less, the CDU performance was evaluated as “good”, and when the value exceeded 4.0 nm, the CDU performance was evaluated as “poor”.

### [Resolution]

The dimension of the smallest resist pattern resolved when the exposure amount was changed was measured, and the measured value was displayed as resolution (nm) in Table 4 in increments of 0.5 nm. The smaller the value, the better the resolution. When the value was 21.0 nm or less, the resolution can be evaluated as “good”, and when the value exceeded 21.0 nm, the resolution can be evaluated as “poor”.

TABLE 4

| | Radiation- | | | Reso- |
|---|---|---|---|---|
| | sensitive resin | Sensitivity | CDU | lution |
| | composition | (mJ/cm²) | (nm) | (nm) |
| Example 1 | R-1 | 58 | 3.7 | 19.0 |
| Example 2 | R-2 | 59 | 3.7 | 19.5 |
| Example 3 | R-3 | 61 | 3.8 | 20.0 |
| Example 4 | R-4 | 59 | 3.8 | 19.0 |
| Example 5 | R-5 | 57 | 3.7 | 20.0 |
| Example 6 | R-6 | 58 | 3.7 | 19.0 |
| Example 7 | R-7 | 59 | 3.8 | 19.0 |
| Example 8 | R-8 | 57 | 3.7 | 19.5 |
| Example 9 | R-9 | 60 | 3.9 | 19.0 |
| Example 10 | R-10 | 61 | 3.6 | 20.0 |
| Example 11 | R-11 | 61 | 3.8 | 20.0 |
| Example 12 | R-12 | 60 | 3.8 | 19.5 |
| Example 13 | R-13 | 60 | 3.7 | 19.5 |
| Example 14 | R-14 | 59 | 3.6 | 19.0 |
| Example 15 | R-15 | 58 | 3.9 | 19.5 |
| Example 16 | R-16 | 59 | 3.6 | 19.0 |
| Example 17 | R-17 | 59 | 3.7 | 19.0 |
| Example 18 | R-18 | 57 | 3.7 | 19.5 |
| Example 19 | R-19 | 63 | 3.8 | 20.5 |
| Example 20 | R-20 | 59 | 3.8 | 20.0 |
| Example 21 | R-21 | 59 | 3.6 | 19.0 |
| Example 22 | R-22 | 60 | 3.8 | 19.5 |
| Example 23 | R-23 | 62 | 3.9 | 20.0 |
| Example 24 | R-24 | 58 | 3.7 | 19.5 |
| Example 25 | R-25 | 59 | 3.8 | 20.0 |
| Example 26 | R-26 | 61 | 3.8 | 20.0 |
| Example 27 | R-27 | 59 | 3.6 | 19.0 |
| Example 28 | R-28 | 58 | 3.5 | 19.0 |
| Example 29 | R-29 | 63 | 3.9 | 20.5 |
| Comparative Example 1 | CR-1 | 59 | 4.3 | 23.0 |
| Comparative Example 2 | CR-2 | 68 | 4.1 | 22.5 |
| Comparative Example 3 | CR-3 | 59 | 4.1 | 21.5 |
| Comparative Example 4 | CR-4 | 60 | 4.2 | 21.5 |

As is apparent from the results in Table 4, the radiation-sensitive resin compositions of Examples were better in sensitivity, CDU performance, and resolution than the radiation-sensitive resin compositions of Comparative Examples.

### INDUSTRIAL APPLICABILITY

According to the radiation-sensitive resin composition and the method for forming a resist pattern of the present invention, sensitivity, CDU, and resolution can be improved as compared with the conventional technology. Therefore, they can be suitably used for the formation of a fine resist pattern in a lithography process for various electronic devices such as semiconductor devices and liquid crystal devices.

1: A radiation-sensitive resin composition comprising:
a resin comprising a structural unit (I) represented by formula (1);
a radiation-sensitive acid generator comprising an organic acid anion moiety and an onium cation moiety; and
a solvent, 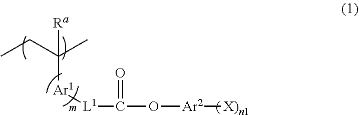
wherein, in the formula (1),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on an Ar¹ side,
Ar² is a monovalent aromatic hydrocarbon group having 6 to 20 carbon atoms and substituted with X,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 to nₘₐₓ, wherein nₘₐₓ is the number of Xs when all hydrogen atoms in the monovalent aromatic hydrocarbon group represented by the Ar² are substituted with X.

2: The radiation-sensitive resin composition according to claim 1, wherein the L¹ is —R^{La}—, —(R^{Lb})_{β}—O—R^{Lc}—, or *—COOR^{Ld}—, R^{La}, R^{Lb}, R^{Lc}, and R^{Ld} are each independently a divalent hydrocarbon group having 1 to 20 carbon atoms, 3 is 0 or 1, and * is a bond on an Ar¹ side.

3: The radiation-sensitive resin composition according to claim 1, wherein the structural unit (I) is at least one of a structural unit represented by formula (1-1) and a structural unit represented by formula (1-2), 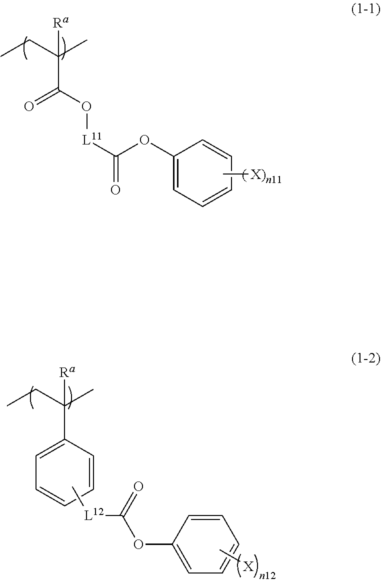
wherein, in the formula (1-1),
R^{a} and X are each as defined in the formula (1),
L¹¹ is a divalent chain hydrocarbon group having 1 to 10 carbon atoms or a divalent alicyclic hydrocarbon group having 3 to 12 carbon atoms, and
n₁₁ is an integer of 1 to 5,
in the formula (1-2),
R^{a} and X are each as defined in the formula (1),
L¹² is **—(R^{12a})_{γ}O—R^{12b}— or **—COOR^{12c}—, R^{12a}, R^{12b}, and R^{12c} are each independently a divalent chain hydrocarbon group having 1 to 10 carbon atoms or a divalent alicyclic hydrocarbon group having 3 to 12 carbon atoms, ** is a bond on a benzene ring side, and 7 is 0 or 1, and
n₁₂ is an integer of 1 to 5.

4: The radiation-sensitive resin composition according to claim 1, wherein X in the formula (1) is an iodine atom.

5: The radiation-sensitive resin composition according to claim 1, wherein the resin further comprises a structural unit having a phenolic hydroxy group.

6: The radiation-sensitive resin composition according to claim 1, wherein the resin further comprises a structural unit having a fluorine atom-containing group.

7: The radiation-sensitive resin composition according to claim 1, wherein a content of the structural unit (I) in the resin to all structural units included in the resin is 5 mol % or more and 40 mol % or less.

8: The radiation-sensitive resin composition according to claim 1, wherein the resin further comprises a structural unit represented by formula (3), 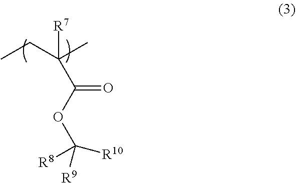
wherein, in the formula (3),
R⁷ is a hydrogen atom, a fluorine atom, a methyl group, or a trifluoromethyl group,
R⁸ is a monovalent hydrocarbon group having 1 to 20 carbon atoms, and
R⁹ and R¹⁰ each independently represent a monovalent chain hydrocarbon group having 1 to 10 carbon atoms or a monovalent alicyclic hydrocarbon group having 3 to 20 carbon atoms, or R⁹ and R¹⁰ taken together represent a divalent alicyclic group having 3 to 20 carbon atoms together with the carbon atoms to which R⁹ and R¹⁰ are bonded.

9: The radiation-sensitive resin composition according to claim 1, the onium cation moiety in the radiation-sensitive acid generator comprises a fluorine-substituted aromatic ring structure.

10: The radiation-sensitive resin composition according to claim 1, further comprising an acid diffusion controlling agent.

11: A resin comprising a structural unit (I) represented by formula (1), 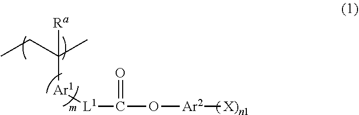
wherein, in the formula (1),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on an Ar¹ side,
Ar² is a monovalent aromatic hydrocarbon group having 6 to 20 carbon atoms and substituted with X,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 nₘₐₓ, wherein nₘₐₓ is the number of Xs when all hydrogen atoms in the monovalent aromatic hydrocarbon group represented by the Ar² are substituted with X.

12: The resin according to claim 11, wherein the L¹ is —R^{La}—, —(R^{Lb})_{β}—O—R^{Lc}—, or *—COOR^{Ld}—, R^{La}, R^{Lb}, R^{Lc}, and R^{Ld} are each independently a divalent hydrocarbon group having 1 to 20 carbon atoms, β is 0 or 1, and * is a bond on an Ar¹ side.

13: A compound represented by formula (i), 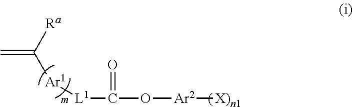
wherein, in the formula (i),
R^{a} is a hydrogen atom or a substituted or unsubstituted monovalent hydrocarbon group having 1 to 10 carbon atoms,
Ar¹ is a substituted or unsubstituted divalent aromatic hydrocarbon group having 6 to 20 carbon atoms,
m is 0 or 1,
L¹ is a single bond, or —O—, *—COO—, a divalent hydrocarbon group having 1 to 20 carbon atoms, or a combined group of two or more thereof, and * is a bond on an Ar¹ side,
Ar² is a monovalent aromatic hydrocarbon group having 6 to 20 carbon atoms and substituted with X,
X is an iodine atom or a bromine atom that substitutes for a hydrogen atom in the monovalent aromatic hydrocarbon group represented by the Ar², and when a plurality of Xs are present, the plurality of Xs are the same as or different from each other, and
n₁ is an integer of 1 to nₘₐₓ, wherein nₘₐₓ is the number of Xs when all hydrogen atoms in the monovalent aromatic hydrocarbon group represented by the Ar² are substituted with X.

14: The compound according to claim 13, wherein the L¹ is —R^{La}—, —(R^{Lb})_{β}—O—R^{Lc}—, or *—COOR^{Ld}—, R^{L}, R^{Lb}, R^{Lc}, and R^{Ld} are each independently a divalent hydrocarbon group having 1 to 20 carbon atoms, β is 0 or 1, and * is a bond on an Ar¹ side.

15: A method for forming a pattern, the method comprising
directly or indirectly applying the radiation-sensitive resin composition according to claim 1 to a substrate to form a resist film,
exposing the resist film, and
developing the exposed resist film with a developer.

16: The method according to claim 15, wherein exposing the resist film comprises exposing the resist film to an extreme-ultraviolet ray or an electron beam.
